(19) United States
(12) Patent Application Publication
(10) Pub. No.: US 2025/0266240 A1
(43) Pub. Date: Aug. 21, 2025

(54) EDITING OF DEEP, MULTI-LAYERED STRUCTURES

(71) Applicant: Carl Zeiss SMT GmbH, Oberkochen (DE)

(72) Inventors: Chris PARK, Pleasanton, CA (US); Brett LEWIS, Woburn, MA (US); Chuong HUYNH, Quincy, MA (US); Shawn MCVEY, Newton, NH (US); Anthony MORIN, Portsmouth, NH (US); John NOTTE, Gloucester, MA (US); Neal SULLIVAN, Lunenburg, MA (US)

(21) Appl. No.: 19/204,136

(22) Filed: May 9, 2025

Related U.S. Application Data
(63) Continuation of application No. PCT/EP2023/025463, filed on Nov. 8, 2023.
(60) Provisional application No. 63/425,782, filed on Nov. 16, 2022.

(51) Int. Cl. H01J 37/305; H01J 37/08

(52) U.S. Cl. CPC H01J 37/3056; H01J 37/08; H01J 2237/0807; H01J 2237/31742

(57) ABSTRACT

An improved system and method for circuit edit or repair within multilayer structures comprising a large number of layers including layers with thicknesses of 20 nanometers or even less, for example less than 10 nanometers or 8 nanometers, are capable of an advanced end-pointing of a milling operation within the large number of layers, including of end-pointing of the thin layers without unnecessarily damaging the multilayer structure.

### CROSS-REFERENCE TO RELATED APPLICATIONS

The present application is a continuation of, and claims benefit under 35 USC 120 to, international application No. PCT/EP2023/025463, filed Nov. 8, 2023, which claims the benefit of priority of U.S. Provisional Appl. No. 63/425,782, filed Nov. 16, 2022. The entire disclosure of each of these applications is incorporated by reference herein.

### FIELD

The disclosure provides a method of editing of deep structures in multi-layers. The method is applicable for circuit edit or extreme ultraviolet (EUV) mask repair. Recent semiconductors and EUV masks have in common a multi-layer structure with many multi-layers of alternating material composition. The method can provide the editing of structures under a stack of multi-layers. The disclosure further provides an apparatus configured for editing of deep structures under a stack of multi-layers.

### BACKGROUND

Editing or repairing of microscopic features of semiconductor wafers or semiconductor masks is widely known as circuit edit or mask repair. For example, “Circuit edit” refers to a modification of integrated circuits in semiconductor wafers of dies. Circuit editing generally involves physically modifying integrated circuits to remove, add or otherwise modify materials to alter a semiconductor feature in a semiconductor chip or wafer, enable additional circuit functionality, characterize the operation of the circuit, or correct the function of or reliable performance of an integrated circuit. In one specific application, circuit edits are performed during the initial stages of the integrated circuit's life cycle to understand or improve the product's performance. Circuit edits are often performed because they can quickly enable the inexpensive prototyping of a circuit modification before the substantial investment in new lithographic masks and repeating the many steps involved in the wafer fabrication process.

Typically, the methods make use of a radiation beam, for example a laser beam or a charged particle beam. The radiation beam is focused onto a region of repair, where a layer of material is either removed or deposited. Typically, precursor gases are provided at a repair site to either provide the material for deposition or to bond to the removed material. Sometimes etching gases are used to augment the removal process to make it more effective, more uniform, or more or less selective milling of one sample material relative to another. For high resolution, as for modern semiconductor with features down to few nanometers, electron or focused ion beams are utilized for editing or repair operations. Focused Ion Beam (FIB) systems, for example, can provide lateral resolutions down to the nanometer regime, and a precise editing or repair of mask or semiconductor features is possible. The pattern of material removal such as trenches or holes of almost arbitrary shape can be formed with high precision. However, the milling rate or rate at which the milled depth increases versus time, depends on various factors, including the material composition of the sample, the geometry of the milled region, the ion current of the focused ion beam as well as the kinetic energy of the ions, and the mass of the ions. The achieved milling depth may further be subject to several uncertainties, like energy spread of the ions, fluctuations in the ion beam current, fluctuations in material compositions, crystallographic orientation, or sample charging, and the like.

Some FIB systems of the prior art use gallium as the ion species. A FIB beam current can vary over many orders of magnitude, with a conventional gallium FIB this can span from a few picoAmperes (pA) to several nanoAmperes (nA). For milling purposes, the areal dosages used by a gallium FIB can be on the order of 1E14 ions per square centimeter (ions/cm²) or more, for example 1E15, 1E16 or higher ions/cm². In another example, a gas field ion beam system has been described. U.S. Pat. No. 8,110,114 B2 describes the use of an ion beam system using a gas field ion source and an activating gas for deposition or removal of material for circuit editing. According to U.S. Pat. No. 8,110,114 B2, using a gas field ion source, an unwanted gallium implantation into a semiconductor substrate is avoided. A gas field ion beam system for mask repair is described in U.S. Pat. No. 9,236,225 B2.

Desired properties for circuit edit and mask repair are becoming more and more demanding. The computer designed patterns of a lithography mask typically have feature sizes comparable to the feature sizes or CD to be produced in the microelectronic circuits on a wafer. Therefore, for microelectronic circuits on a wafer as well as the features on lithography masks, dimensions of features or patterns are becoming ever smaller, for example below 20 nanometers (nm), below 10 nm, below 5 nm, below 3 nm or even less. With these actual and future critical dimensions (CD), also the placement of the semiconductor features or mask features becomes more and more demanding. The pattern placement is typically correlated with the overlay properties, which is typically specified by a fraction of the CD, for example one third or less of the CD. According to the overlay properties, the features in different layers within a micro-electronic circuit on a wafer overlap with even higher precision, with deviations for example below 2 nm or even below 1 nm.

Semiconductor masks typically have a topography formed by the absorbing structures on top of the mask material. Absorbing structures are typically formed by lithographic processing of an opaque film, for example a chrome film of up to a thickness of tens of nm. Other materials or structures can be employed as well, for example for phase shift masks. For EUV masks, also other absorbers can be employed as for example thin tantalum films or silicon nitride. Features for phase shifting in EUV masks can be buried features, which are covered by a reflective multi-layer stack.

Recently, the number of layers in a typical semiconductor circuit has been increasing. For example, NAND memory devices of processors comprise about 100 layers, and even higher numbers of layers will be achieved in near future. Each layer may be formed as a conducting layer, with conducting features embedded within isolating material. The layers may be separated by isolating layers with some vias or through connections. Isolating material is typically formed by silicon oxide or silicon nitride, while conducting features are formed by doped silicon or metals, comprising for example copper, aluminum, or tungsten. After each layer is formed by a lithography process and etching or implantation, each layer is planarized and a next layer is formed on top of it. The layer thickness can thus be very small, for example 50 nm, 20 nm, 10 nm or even less. A repair site or circuit edit site might be covered by a multi-layer structure comprising up to 100 or even more thin semiconductor layers. The same layered structure applies to EUV masks. EUV masks typically are formed by at least one multilayer-stack comprising at least thirty or more mono-layers of Molybdenum and Silicon. In this case, each layer pair has a thickness of about a half of the EUV wavelength of 13.4 nm. Further thin diffusion barrier layers may be formed between the layers.

### SUMMARY

The disclosure seeks to provide an editing method for a deep structure within or below a multi-layer stack. The disclosure seeks to provide a milling method for a precision-controlled removal of a multi-layer stack above a deep structure. The disclosure seeks to provide a circuit editing or mask repair method with a lateral accuracy of below 1 nm and a milling or depositing accuracy in depth of below 1 nm. The disclosure seeks to provide a circuit editing operation of deep semiconductor structures within highly integrated, multi-layer semiconductor circuits on a chip or wafer. The disclosure seeks to provide a mask repair or mask editing operation of deep structures within an EUV mask. The disclosure seeks to provide an apparatus capable of performing an editing method for a deep structure within or below a multi-layer stack.

According to a first embodiment of the disclosure, an improved edit or repair system comprises a source chamber with a gas field ion source for generating an ion beam, an ion beam column, and a sample enclosure. Gas nozzles connected via precision valves are configured for providing different source gases to the gas field ion source. In an example, two or more gas supply nozzles are configured for providing two or more gases, for example helium and neon. However, further gases can be used as well, including other noble gases like argon, or other gases from materials of low atomic mass number below 40, for example hydrogen or nitrogen. The ion beam generated by the ion beam source is further focused by objective lens of the ion beam column to form an ion beam focus on the surface of the sample.

The sample can be mounted on a sample stage, which can be moved and controlled in six degrees of freedom. Further, a detector can be arranged in the sample enclosure. The detector can be configured to attract secondary particles, which are generated as interaction products by interaction of the ion beam with the sample. Interaction products can be secondary electrons, sputtered ions, secondary photons, or scattered primary ions. Typically, the detector comprises a charged grid to attract charged particles, and a detector such as a PMT.

During use, the components of the repair system can be controlled by an operation control unit with several components or units including a processor and a memory to store software instructions.

An image acquisition control unit can be connected to a detector and scanning deflectors. During an image acquisition, the focused ion beam can be deflected in a predetermined scanning path across the surface of a sample, and the intensity signal of interaction products is detected for each scanning position and stored at memory locations corresponding to the scanning position in a memory of the image acquisition unit. Thereby, image acquisition and scanning can be performed during use in synchronized operation and a 2D image of an area of the sample surface is obtained.

A source control module can be responsible for controlling during use the operation of the ion beam source. The source control module is connected to the for example two precision valves, by which the source gas concentration is adjusted during use. During a milling or an imaging process, the repair system can thereby be configured to operate at low areal dosage of ions, for example one million ions per square micrometer (ions/μm²) or even less, for example 10.000 ions/μm².

The source control module can be configured to select and adjust ion species during use. In an example, the source control module is configured for supplying neon by a first precision valve into the source chamber and configured for supplying helium by a second precision valve into the source chamber. The repair system can therefore be configured for switching during use between a first ion beam with a first ion current and a second ion beam with a second ion current. The repair system can be further configured for a switching during use between different ion species for improved monitoring or even further reduced milling rates. In an example, the repair system is configured to operate with a mixture of ions, for example Neon and Helium. The ratio of the gas mixtures can be adjusted during operation by precision nozzles in a wide range, for example 50:50 or 30:70 or 10:90 mixing ratio between the first and second ion species. Thereby, a secondary electron yield (SEY) and a sputtering yield (SY) can be further optimized for example depending on the desire to image with low sputtering, or the desire to deliberately sputter the sample. Thereby, an SEY and an SY can be further optimized for example depending on the material composition of a sample, and an even further reduction of a layer damage during ion beam scanning of an area of a sample can be achieved.

The edit or repair system can be configured for exploiting the following features.
a) The repair system t is configured for a higher SEY and a high lateral resolution.
b) The repair system is configured for an imaging operation with a lower sputter rate, for example with a ratio of SEY to SY (SEY/SY) of greater than 1.5, for example 3, 5, 10, 20, 50 or even more.
c) The repair system is configured for an operation with a lower ion beam current.
d) The repair system is configured for a repair or edit operation with a reduced generation of damages to a structure at the repair site.

In an example, the source control module is further configured for a precise control of an ion beam current down to currents below few pA, for example below 1 pA, or even below 0.1 pA. Thereby, the milling process can be appreciably slowed so the desired depth resolution can be attained. In an example, the Neon ion beam energy can be adjusted with the source control module to below 10 kilo electron volts (keV), for example 6 keV, 5 keV, 4 keV, or 1 keV. Thereby, an ion implantation into large depths is reduced and a smoother surface is achieved during milling. With smoother surfaces, end-pointing of an ion-beam-milling can be improved.

In a further example of the repair or edit system according to the first embodiment, the sample is arranged within a sample chamber or process chamber, in which a gas nozzle is arranged for the supply of at least one precursor gas. A gas nozzle is provided with a valve and connected to at least one reservoir of precursor gases. Precursor gases can comprise at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PM CPS, Tungsten Hexacarbonyl, Water, or Xenon Difluoride. Other gases are, however, possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, Formic acid, Formamide, A cetamide, N-methylacetamide, Propionyl Chloride, Propanioc acid, N,N-dimethylethanamide, Nitro acetic acid, Butyric acid, Lactic acid and combinations thereof.

With the addition of precursor gases, a homogeneity, or uniformity, or selectivity of a milling operation can be improved and a redeposition of milled material from the multilayer structure can be reduced. For some precursor gases the ion beam can cause deposition of materials as an additive process.

According to the second embodiment of the disclosure, an improved method of ion-beam milling of a deep trench through a multilayer structure with precision end-pointing at a transition to a predetermined deep layer can be provided. The method comprises the steps of performing a first mode of fast milling to a first end-point. The first end-point corresponds to a first transition zone or trigger, at which an operation condition of the ion beam system is changed. When a first milling depth in proximity of the first end-point is reached, a switching step to a second mode of precision milling and a second mode of precision milling is performed until a second end-point is reached. In an example, the second endpoint is corresponding to the transition to the predetermined deep layer. In an example, second endpoint corresponds to a second transition zone or trigger, at which an operation condition of the ion beam system is changed again and a switching step to a further mode of precision milling and a further mode of precision milling is performed until a further end-point is reached.

During the first mode of fast milling, a first ion beam with a first ion beam current is used, wherein the first ion beam comprises at least a first ion species. In an example, the first ion species has a mass number below 40, for example the first ion species is Neon. During the first mode of fast milling, a first ion beam is scanned with a first scanning condition over a designated surface area. In an example, the method comprises the step of determining an actual milling depth during performing the first mode of fast milling and the step of determining whether the actual milling depth is approximately corresponding to the first end-point. The step of determining the actual depth can comprise for example the step of determining an integrated milling dose during the first mode of fast milling and comparing the integrated milling dose to a predetermined milling dose for the stack of multilayers. The predetermined milling dose is for example determined from a sequence of layer thicknesses and material compositions of the multilayer structure within the milled area. The predetermined milling dose is for example computed from designed thickness and material composition, for example from CAD information of the multilayer structure. In an example, the step of determining the actual depth relies on test sites that have been cross sectioned and imaged at a tilted perspective. Alternatively, the actual depth can be inferred from the variations in the detected secondary electron (SE) signal as it mills progressively deeper. Significant increases or decreases in this signal can be correlated with different material layers. In an example, the step of determining the actual depth comprises for example determining an area-integrated SE signal during the first mode of fast milling and comparing the area-integrated SE signal to a predetermined SE signal for the stack of multilayers. The predetermined SE signal is for example computed from layer thicknesses and material composition within milled area. The predetermined SE signal is for example computed from CAD information of the multilayer structure. In an example, the area-integrated SE signal is collected from a reduced area of a milling area within the deep trench.

During the second mode of precision milling, a second ion beam with a second ion beam current can be used. The second ion beam may have different energy, or different ion current, or different ion species, or different scanning conditions. During the second mode of precision milling, a second ion beam can be scanned with a second scanning frequency over a surface area of the trench created during the first mode. In an example, the ratio of a yield of secondary charged particles SEY and a sputtering yield SY of a multilayer material of the multilayer structure during the second mode of precision milling is larger or equal to 1, or SEY/SY>=1, for example SEY/SY=1.5. In an example, the second ion beam current is lower compared to the first ion beam current. In an example, the second ion beam comprises the first ion species with reduced ion dose or concentration ratio. In this example, the step of switching to the second mode of precision milling further comprises the step of reducing a gas delivery of a first ion species to an ion-beam source. The second ion beam may comprise a second ion beam species, and the method may comprise the step of changing a gas delivery to an ion-beam source to add the second ion beam species to the second ion beam. The second ion beam species can for example be Helium. The provision of a second ion species can further be combined with the step of reducing the gas delivery of a first ion species to an ion-beam source. Thereby SEY/SY, during the second mode of precision milling can be further increased to be greater than 1.5, for example greater than or equal to 2, for example greater than 10. In an example, the second scanning frequency is greater than the first scanning frequency. Thereby, a damage to the multilayer structure during the second mode of precision milling can be reduced.

In a further example, the method according to the second embodiment further comprises the steps of acquiring of a surface image of an actual milled surface at an actual depth and determining the actual depth within the multilayer stack from the surface image. The step of determining the actual depth can comprise for example a comparison of the surface image with CAD data. The step of determining may further comprise at least one of an image processing, feature extraction, or pattern detection. In an example, the step of acquiring of a surface image is performed during the second mode of precision milling. In an example, the step of acquiring of a surface image is performed during the first mode of fast milling. In an example, the step of acquiring of a surface image further comprises a switching the first or second ion beam to a third ion beam, wherein the third ion beam has a different energy, different current, different ion species, or different scanning pattern. In an example, the third ion beam has ratio of a yield of secondary charged particles SEY with a sputtering yield SY of a multilayer material of the multilayer structure larger than 10, or SEY/SY>10, and acquiring of the surface image of the actual milled surface with the third ion beam. The step of switching to the third ion beam comprises for example the step of changing a gas delivery to an ion-beam source to either add a third ion beam species to the first or second ion beam, and/or to reduce a gas delivery of an ion species of the first or second ion-beam. For example, Helium ions are added to the third ion beam, while the ion current or concentration of other ion species such as Neon are reduced.

In a further example, the method according to the second embodiment further comprises an adjustment of a milling area of subsequent milling operation to an edit location. The adjustment may be based on the surface image. The adjustment of the milling area is for example performed according to CAD information. In an example, the method further comprising the step of determining a position of a milling area of the deep trench to be milled with respect to an edit location.

In a further example, the method according to the second embodiment further comprises the steps of acquiring a surface image of an alignment fiducial and performing an alignment step of the position of the milling area of the deep trench. After alignment or re-alignment, a milling operation according to the first or second mode of operation can be continued. Thereby, a damage to the multilayer structure can be minimized. In an example, the method comprises the step of forming an alignment fiducial close to the position of the milling area. The position of the milling area is for example determined from CAD information of the multilayer structure. The step of alignment comprises for example a step of driving at least one precision actuator of a sample stage for holding the multilayer structure or a precision voltage supply to an ion beam deflector for scanning the ion beam. Thereby, a position of the multilayer structure can be adjusted with respect to an ion beam.

In a further example, the method according to the second embodiment further comprises the steps of performing drift monitoring of a position of the multilayer structure with respect to an ion beam axis and performing a drift compensation during first or second mode of operation. The method may further comprise the step of computing compensation signals and providing the compensation signal to short stroke control electronics to generate at least one control signal of a sample stage or an ion beam deflector.

In a further example, the method according to the second embodiment further comprises more than one second precision milling step. By iteratively refining the precision milling step to even smaller milling rates of even larger ratio of SEY to SY by for example changing the dose or current of an ion species, a fast and nevertheless very precise approaching of a repair layer can be achieved, without causing unnecessary damage to a microelectronic circuitry.

In a further example, the method according to the second embodiment further comprises the steps of providing a precursor gas into sample or process chamber via a gas nozzle. Precursor gases can comprise at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PM CPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, Formic acid, Formamide, A cetamide, N-methylacetamide, Propionyl Chloride, Propanioc acid, N,N-dimethylethanamide, Nitro acetic acid, Butyric acid, Lactic acid, and combinations thereof. With the selected precursor gases, a more homogeneous milling of the multilayer structure can be achieved during use. Other selected precursor gases can allow for insulating or conductive materials to be deposited by the ion beam. A multilayer structure comprises for example conductors such as aluminum or copper embedded in semiconductor materials such as doped silicon, silicon oxide or silicon nitride.

The disclosure further includes a FIB system with a control operator with a processor and a memory and software installed, configured to perform a method according to the second embodiment. With the repair or edit system according to the first embodiment, the method according to the second embodiment, a circuit edit operation is made possible also for thick multilayer structures, comprising a large number of multilayers and even comprising thin multilayers of thicknesses below 20 nm, below 10 nm or even less. Especially, with an SEY/SY ratio greater or equal to 1, or SEY/SY>1, a relatively precise milling of deep thin layers can be achieved during the second mode of precision milling without unnecessary damage to the deep thin layers of layer thicknesses below 20 nm. With a further increased SEY/SY ratio of greater than or equal to 2, such as greater than 2 or greater than 10, a milling rate during an image generation for precision end-pointing can be further reduced, and it is possible to perform an end-pointing of thin layers with layer thicknesses below 10 nm. M ore features of the embodiments of the present disclosure will become apparent from the following description in conjunction with the accompanying drawings. The disclosure is not limited to the embodiments and examples, but also comprises variations, combinations, or modifications thereof. Other embodiments of the disclosure will be apparent to those skilled in the art from consideration of the specification and practice of the disclosure disclosed herein.

### BRIEF DESCRIPTION OF THE FIGURES

FIG. 1 shows a cross section of an example of a repair site at a sample with a plurality of layers.

FIG. 2 shows a top view from the example of a repair site.

FIG. 3 shows an example of a milling of a trench.

FIG. 4 illustrates an example of a secondary electron signal according to a known method.

FIG. 5 illustrates an example of a repair system according to the disclosure.

FIG. 6 illustrates an example of a flow chart for a repair method according to the disclosure.

FIGS. 7A-7B illustrate a milling step and a SE signal according to a first operation mode.

FIG. 8 illustrates an end-pointing according to a first operation mode.

FIG. 9 illustrates an end-pointing according to a second operation mode.

FIGS. 10A-10C illustrate examples of a surface images obtained during the second or third operation mode.

### DETAILED DESCRIPTION

Reference will now be made in detail to exemplary embodiments, examples of which are illustrated in the accompanying drawings. Throughout the description same numbers in different drawings represent the same or similar elements unless otherwise represented. The coordinate system is selected with the z-axis parallel to an ion beam, with positive z-direction in the propagation direction of the ion beam. The terms “above” or “below” in this disclosure are relative terms and depend on the orientation of the wafer with respect to the ion beam of an ion beam system.

This disclosure describes certain advantageous techniques for achieving successful circuit edits or mask repairs at the smallest scales. The described techniques involve the use of the gas field ion source (GFIS), and a novel method of using a focused ion beam. Factors such as redeposition and enhanced sputter yield at different angles are factors that experts in this field will be familiar with. Experts in this field are also familiar with enhancement of the milling rate with the addition of etching gases facilitating higher material removal rates or making them more or less selective to different materials or different crystalline orientations.

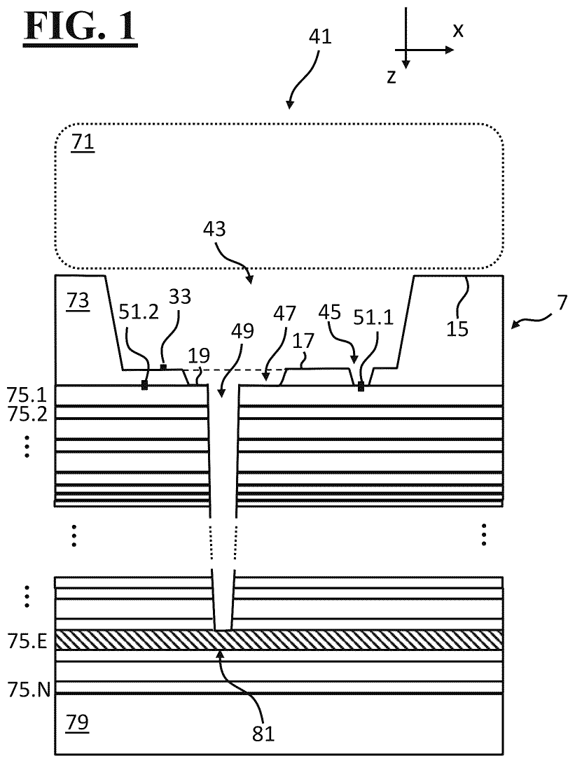

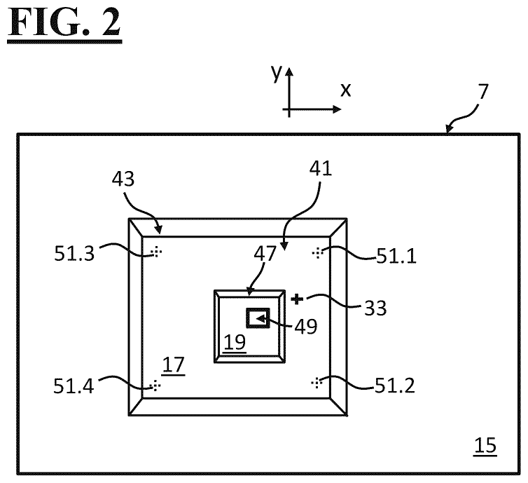

A simplified model of a semiconductor wafer 7 with several layers 75.1 to 75.N of different composition is shown in cross section in FIG. 1. For simplicity, the lateral details of the integrated circuits in the layers 75.1 to 75.N are omitted in the figures. The figures the result of the preliminary steps to prepare the semiconductor wafer 7 at a repair site 41 for a circuit edit operation. The multi-layer stack 75.1 to 75.N of the semiconductor wafer 7 may comprise N=100 or more layers. In the example, a circuit edit or repair location 81 is in repair layer 75.E, which is covered by a large number of layers. A layer number of a deep repair layer 75.E may be at least E>10, E>30, E>50, E>80 or even E>100. Each layer of the multilayer structure comprises for example conductors such as aluminum, tungsten or copper embedded in semiconductor materials such as doped silicon, silicon oxide or silicon nitride. FIG. 2 shows a top view of the same repair location 41.

In an example, the circuit editing may proceed from the backside (through the silicon substrate) of a processed wafer 7. To access the semiconductor features in question may involve the removal of bulk material 71 of the wafer 7. A wafer may have a thickness of about several 100 μm to 1 mm. Bulk removal methods are used to eliminate unneeded packaging or bulk silicon. Bulk removal techniques can include mechanical machining, grinding, polishing, laser processing, chemical etching, or some combination of these methods, including chemical mechanical polishing (CM P). The disclosure, however, is not critically dependent on the orientation of the semiconductor wafer 7 relative to the circuit edit activities (e.g. edit from front side or back side). In an example, the semiconductor wafer 7 may comprise a further layer 79 below the multi-layer stack 75.1 to 75.N.

After the optional bulk removal, a local trench 43 is created into the surface 15 at the area surrounding the edit site 41 to allow for better access. The location of the inspection site 41 and of the trench 43 can be based on different information, for example a failure analysis of the semiconductor wafer 7 or CAD information and can be aided by optical or infrared microscopy which can penetrate the remaining silicon and see navigation fiducials 51.1 and 51.2 before performing the milling operation of trench 43. Navigation fiducials 51 are typically present in the fabricated semiconductor wafer 7. The trench 43 can be created by micro-scale techniques which include laser processing, masked etching using a plasma FIB with etch masks, or FIB operating with high beam currents. The lateral extension of the trench 43 can be several 10 μm, for example 50 μm 100 μm, 200 μm or even more. The depth of the trench is selected down to surface 17, which is selected slightly above and nearly exposing the surface 19 of the first semiconductor layer 75.1 of active devices, which are the object of the circuit edit task. The exposed or nearly exposed navigation fiducials 51.1 and 51.2 (only two shown, but there might be more) serve as alignment markers which can be used as location references relative to CAD information (i.e. blueprints) for the subsurface design features of interest. In this way, the semiconductor wafer 7 can be registered with respect to for example CAD information and subsequent activities can be aligned with high precision in lateral X,Y-direction to access the subsurface features at repair location 81 that involve editing. In an example, a local trench 45 is formed by precision FIB milling to fully expose a present alignment fiducial 51.1. In an example, a further alignment fiducial 33 is formed close to a lateral position of the repair location 81.

After milling of trench 43 is complete, more precise techniques are used to mill down to the repair location 81. In a first step, a second trench 47 can be formed to expose the surface 19 of the first layer 75.1. Deep milling through the stack of multi-layers 75.1 to 75.E is performed to form deep trench 49 down to the repair location 81. According to the disclosure, a precision Ion beam milling with low beam energies and low beam currents is applied. By utilizing low beam energies and low beam currents, the precision milling proceeds slowly, and sub-surface defects are minimized. During the precision milling down to the repair location 81, features present in the layers 75.1 to 75.E are destroyed. To minimize the unwanted destruction of features present in the layers 75.1 to 75.E, the extend of the deep trench 49 is kept small. According to the disclosure, the depth of the formation of trench 49 by precision milling down to the repair location 81 is determined by an improved method of precision end-pointing.

With the above preparations complete, including the formation of the deep trench 49 down to the repair location 81, the actual circuit edit region is exposed and is subject to the circuit edit activities, including both additive and subtractive processes. The additive processes involve a gas injection system (GIS) which deliver volatile precursors which under the presence of the ion beam are condensed to leave conductors or insulators in precise arbitrary patterns. The subtractive processes include milling, or gas assisted focused ion beam milling. These processes demand precision end-pointing to be sure that the material removal is at the correct depth.

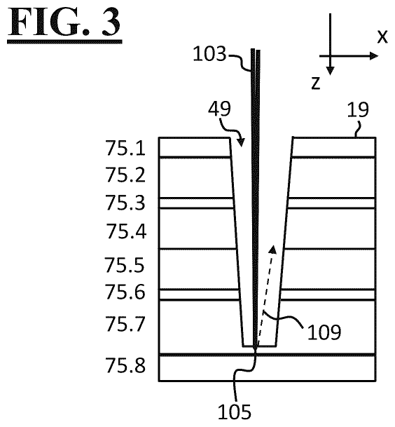

In a conventional FIB milling process, during the process of the FIB milling of a trench, the depth of the milling operation is monitored by secondary electrons generated during the milling operation. An example is illustrated in FIG. 3. FIG. 3 illustrates eight layers 75.1 to 75.8. A trench 49 is milled by ion beam 103 down into layer 75.7. FIG. 3 shows the milled region through the first six layers 75.1 to 75.6 and stopping in the middle of the 7th layer 75.7. At the intersection point 105 of the ion beam 103 with the remaining sample surface, secondary electrons (SE) 109 are generated. Generally, during ion beam milling according to the prior art, a tapered hole is formed. Such an example is shown in FIG. 3. For example, if the area to be milled is desired to be a 40 nm×40 nm square, the cross section of the trench 49 at the top surface 19 will typically be wider (e.g. 50×50 nm, or 60×60 nm, or 80×80 nm, etc.) and the area of the cross section in a deeper layer, for example layer 75.7 is narrower (e.g. 35×35 nm, 30×30 nm, 25×25 nm, etc). Correspondingly the sidewalls of the trench 49 form an angle which is deviating from 90 degree with respect to the surface 19 (e.g. sidewall angles that are measured with respect to the top surface 19 as less than 85 degrees, less than 80 degrees, less than 75 degrees, or even less). The tapered shape of the trench 49 is due to the beam profile of for example a gallium ion beam and due to a re-deposition of sputtering products. This effect results in undesired larger damage at the top surfaces, where the cross section of the trench 49 is wider than desired. This effect may also result in insufficient exposure at the bottom surface, for example in layer 75.7. The cause of the undesired milling profile is re-deposition of sputtering products, including gallium, and the low-quality beam profile of for example a focused gallium beam.

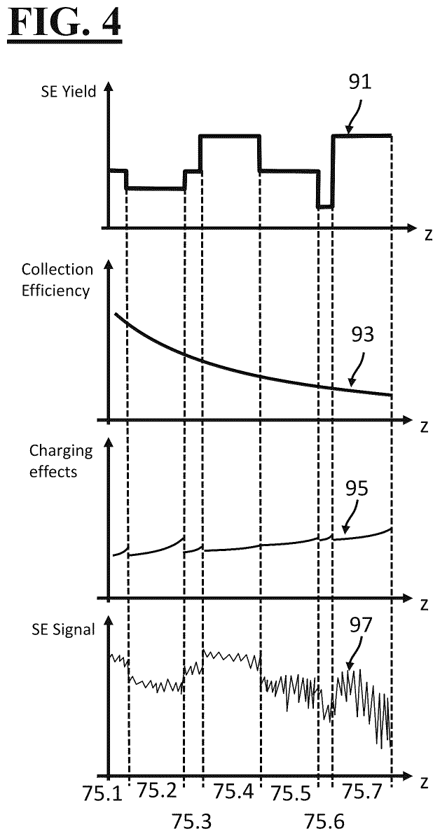

Conventionally, a Gallium ion beam is used, and the end-point signals are derived from detectors and electronics designed to respond to the generation of secondary electrons (SE). The SE signal vary based on the composition and thickness of the various layers. The SE signal is influenced by the yield of secondary electrons SE. The SE yield depends on the different material composition of the layers 75.1 to 75.7 and the ion properties used in the ion beam 103. In ideal cases, a distinctive and measurable change of SE signal is detected as the different layers are progressively milled through by the incident ion beam. Averaging can be used to smooth out what is otherwise a noisy signal, making the endpoint signature more evident. M ore sophisticated signal processing techniques including median filters, derivative filters, low pass filters, history-based algorithms, and their like can be used to make the endpoint signal more evident. In some cases, the integrated circuit in question can be actively operated for example driving voltages at certain frequencies and looking for the presence of this same frequency signature in the detected signal (lock in amplification technique). Several factors, however, complicate the effective use of the endpoint signal in deep trenches. Some effects are listed in the following examples and FIG. 4 illustrates the corresponding secondary electron (SE) signal 97. The SE signal 97 depends on the SE yield 91 of the ion beam within the actual material composition of a layer.
(a) The SE signal 97 depends on the collection efficiency 93. There is generally a reduced signal collection as the milling proceeds deeper and the generated secondary electrons are increasingly unable to escape the milled hole for detection. The collection efficiency 93 is determined by the geometry and decreases with increasing depth of the trench 49. One way of the prior art to increase collection efficiency is to increase the lateral extension of trench 49 at the expense of a larger damage to the semiconductor features at the repair site 41.
(b) There can be fluctuations in the signal attributed to current fluctuations in the ion source. While a fluctuation in current can be monitored and considered, there is a remaining fluctuation in the detected signal due to the statistical nature of the number of ions in the ion beam, which is generally described by Poisson statistics.
(c) The detected SE signal 97 exhibits fluctuations because the SE generation process is also described by Poisson statistics. With reduced SE signal 97 due to the reduced collection efficiency 93, a noise contribution to the SE signal 97 increases with increasing depth, and a signal to noise (SNR) ratio is reduced.
(d) The detected signal is also impacted by mixing effects as the incident ion beam tends to mix atoms from one layer to deeper layers.
(f) As some layers are insulating layers, there can be charging artifacts 95 that reduce the detectable signal. In addition, some secondary electrons might stick to the boundaries of the trench 49, which further influence the SE signal 97.
(g) There is often a lateral drift of the sample relative to the ion beam while the milling takes place, causing bright edge artefacts that complicate the interpretation of the signal. Even a well-controlled ion beam system will exhibit drifts on the order of 3 to 5 nm/minute. As semiconductor features become smaller and smaller, these become increasingly significant.

Furthermore, the precision or accuracy of end-pointing is limited by the ratio of the sputter yield SY and the secondary electron (SE) yield. This sputter yield SY describes the sputtered atoms of the sample for each impinging ion and depends on the material in question, the angle of incidence, the energy of the ions used. The SE yield describes the secondary electrons generated from the sample for each impinging ion and depends on the material in question, the angle of incidence, the energy of the ions used. The sputter yield determines the depth which will be sputtered away in the process of acquiring a reasonable low noise image. Due to the sputter yield, during any acquisition of a useful image signal with a sufficient SNR, a surface layer is a milled down to by a certain amount due to the sputter yield, i.e. end-pointing in depth may not exceed an accuracy of better than described by the ratio of the sputter yield versus the secondary electron yield. The smaller the secondary electron yield or the larger the sputter yield, the less accurate an end-pointing can be and the more a sample gets damaged during an ion beam scanning across an area of the sample.

A gallium FIB of the prior art has a low SE yield compared to the sputtering yield (SY) and does produce a much weaker SE signal during sputtering. In a typical example, a representative number of the sputter yield of gallium is about SY=17. Each gallium ion also yields a number of secondary electrons (SE Yield) which is in the same example SEY=2. This example illustrates that in systems of the prior art, utilizing Gallium ion beam, even when using the gallium ion beam for imaging, a substantial part of a semiconductor layer is removed. For example, with Gallium ions, during the acquisition of a useful end-pointing signal with a SNR of about five, a surface layer is a milled down to a depth of about 20 nm, i.e. end-pointing in depth may not exceed an accuracy of better than 20 nm. Any time an image is acquired, a surface area is damaged down to a depth of at least 20 nm.

These confounding effects present challenges to the conventional usage of ions beam for circuit edit or mask repair. With the conventional methods, the SE signal 97 can only be used for discriminating layers 75 of shallow depth, for example layers 75.1 to 75.5, but with increasing depth the depth discrimination or detection of different deep layers becomes more and more challenging. In the example illustrated in FIG. 4, a discrimination below layer 75.5 is not possible anymore. With increasing depth, the generated SE signal 97 only provides some rough indication of the current depth and a proper end-pointing of the milling of trench 49 is not possible anymore. In the absence of an unambiguous endpoint signal to monitor, a milling operation is left to a method described as ‘dead reckoning’. In this case, a measured probe current, and an estimated milling rate are used to correlate a given ion beam dosage (in ions/cm\hat{ }2 for example) to a known depth in the given material. Furthermore, with FIB systems using Gallium, a controlled removal of thin layers with a thickness of less than 20 nm is not possible, since at any reasonable operation, a layer of more than 20 nm thickness is removed by the Gallium ion beam. These issues are addressed and solved by the embodiments of the disclosure.

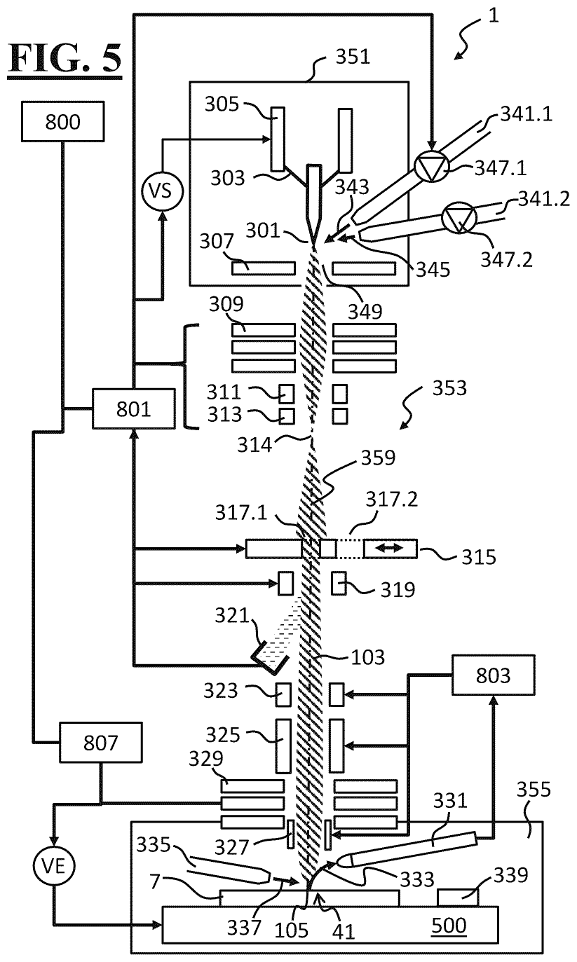

FIG. 5 illustrates a repair system 1 according to a first embodiment of the disclosure. The repair system 1 comprises a source chamber 351 with a gas field ion source 349 for generating an ion beam 103, an ion beam column 353, and a sample enclosure 355. The repair system 1 is operated at high vacuum and connected to several vacuum pumps (not shown). In the source chamber unit 351, the source tip 301 is provided and connected via a heating wire to mounting posts 305. The source tip 301 can be formed by few atoms, for example one or three atoms of tungsten. The source chamber 351 is further connected to a vacuum pump (not shown), by which a low vacuum pressure inside the source chamber 351 is maintained. An ion species is generated at the source tip. The ion species depends on the gas provided by gas nozzles 341.1 and 341.2 into the evacuated source chamber 351. The gas nozzles 341 are connected to gas supply units (not shown) for connecting the source chamber to different source gases. The gas nozzles 341 are configured with precision valves 347.1 and 347.2, by which the partial gas pressures inside the source chamber 351 is adjusted. In the example of FIG. 5, two gas supply nozzles 341.1, 341.2 are shown, for providing two different noble gases, for example Helium 343 and Neon 345. However, more than two gas nozzles 341 can be provided and further gases can be used as well, including other noble gases like Argon, or other gases from materials of low atomic mass, for example Lithium or Nitrogen. The ions generated at source tip 301 are accelerated by the extractor electrode to up to 30 keV. In an example, a source potential is adjusted to +30 keV by providing VS=30 kV to the source tip 301. Generally, an ion beam energy can be adjusted to lower energies as well, for example below 20 keV, 10 keV, for example 6 keV, 5 keV, 4 keV, or 1 keV.

The gas atoms 343, 345 now ionized and passing the aperture of the extractor electrode 307 are leaving the source chamber 351 through an aperture and are collimated and focused by at least one condenser lens 309 to form an intermediate source image 314. The condenser lens 309 can comprise several lenses, by which for example a magnification of the source image 314 can be adjusted. Thereby, a source current and a resolution can be adjusted. The condenser lens can be configured as an electrostatic lens comprising at least three electrode plates. However, the condenser lens can also be a magnetic lens or a combination of magnetic and electrostatic lenses.

In proximity of the condenser lens 309, two multi-pole elements 311 and 313 are arranged to correct a propagation angle of the ion beam 103 or as a first mechanism to compensate aberrations of the ion beam 103. Downstream of the intermediate image 314, the ion beam 103 passes an aperture stop 317.1 arranged on an aperture stop carrier 315. Thereby, a diameter of the ion beam 103 as well as an ion current can further be adjusted. The ion beam 103 traverses a beam deflector 319, by which during use the ion beam 103 can be deflected into a beam dump 321. The beam dump 321 can be configured as a Faraday cup, by which an ion beam current can be measured. With the beam deflector 319 in off mode, the ion beam 103 further propagates through multipole elements 323 and 325, by which during use the ion beam 103 is deflected in a scanning mode across the surface of object 7. The ion beam 103 is further focused by objective lens 329 to form an ion beam focus 105 on the surface of the sample 7. The objective lens 329 can be configured as an electrostatic lens comprising at least three electrode plates. However, the objective lens 329 can also be a magnetic lens or a combination of magnetic and electrostatic lenses.

The sample 7 is mounted on a sample stage 500, which can be moved and controlled in six degrees of freedom. Such sample stages 500 are known in the art and comprise for example laser interferometers or a similar mechanism for position control. A stage 500 can comprise a first stage with long stroke actuators and a second stage with short stroke actuators with precision control within the nm-region. Via the sample stage 500, a repair site 41 is arranged in proximity of the column axis 359, with the sample surface perpendicular to the column axis 359. During use, the sample stage 500 is configured to hold the sample surface in the focus plane of the ion beam column 353. Via the sample stage 500, a decelerating voltage VE can be provided to the sample 7. With the sample voltage VE, a further adjustment of the focus position is possible. Further, a sample current corresponding to the absorbed charge from the ion beam 103 can be measured.

The sample 7 is arranged within a sample chamber or process chamber 355, in which a gas nozzle 335 is arranged for the supply of a precursor gas 337. The process chamber is provided with a load lock (not shown) for transfer of the sample 7. A gas nozzle 335 is provided with a valve (not shown) and connected to at least one reservoir of precursor gases. Further, a detector 331 is arranged in proximity of the interaction volume of the ion beam 103 with the sample 7. The detector 331 is configured to attract charged particles, which are generated as interaction products 333 by interaction of the ion beam 103 with the sample 7. Interaction products 333 can be secondary electrons, secondary ions, or scattered primary ions, or photons. Typically, the detector 331 comprises a charged grid to attract charged particles, a scintillator to convert charged particles to photons, a light guide and a photon-detector such as a PMT. A further calibration sample 339 can be provided on the sample stage 500. The sample enclosure 355 is further connected to a vacuum pump system, comprising such as a turbo-molecular pump, an ion pump, a getter pump, a cryo-pump, a titanium sublimation pump or the like (not shown).

During use, the components of the repair system 1 are controlled by an operation control unit 800. Some features of the operation control unit 800 are illustrated in further detail. A source control module 801 is responsible for controlling during use a source operation. The source control module 801 is connected to the voltage supply for providing the source voltage VS and extractor voltage (not shown). The source control module 801 is connected to the precision valves 347.1 and 347.2, by which the source gas concentration can be adjusted during use. The source control module 801 is further connected to the condenser lens 309 and the first and second multi-pole elements 311 and 313, by which the formation of the intermediate source image 314 is controlled. Source control unit 801 is further connected to the aperture stop carrier 315, which is configured for a change of the apertures stop 317.1 or 317.2 during use. Source control module 801 is further connected to beam dump 321 and configured for determining and controlling the ion beam current during use.

A focusing control unit 807 is connected to the objective lens 329 and the sample voltage supply. Focusing control unit 807 is configured to adjust the focus spot position of focus spot 105 on the surface of the sample 7. An image acquisition control unit 803 is connected to image sensor 331 and scanning deflectors 323, 325 and 327. During an image acquisition, the focused ion beam 103 is scanning deflected in a predetermined scanning path across the surface of the sample 7, and the intensity signal of interaction products 333 is detected for each scanning position and stored at memory locations corresponding to the scanning position in a memory of the image acquisition unit 803. Thereby, image acquisition and scanning are performed during use in synchronized operation and a 2D image of an area of the sample surface is obtained. A first scanning operation of the ion beam 103 is controlled by the third and fourth multi-pole elements 323 and 325. With the combined action of the third and fourth multi-pole elements 323 and 325, a deflection position of the ion beam 103 and an angle of incidence of the ion beam 103 at the surface of the sample 7 can be adjusted. A typical scanning frequency of about 0.1 kHz to 20 kHz can be achieved, corresponding to a dwell time between 0.1 us to 10 μm. A fine adjustment of a position of the focus points of the ion beam 103 can be achieved by the fifth deflector 327. The multipole elements 323, 325 and 327 can further act either alone or in combination to adjust or compensate an aberration of the ion beam 103. Thereby, a small probe size with high resolution of below 3 nm or even less can be achieved with a position accuracy of below 1 nm.

In an alternative example, the objective lens 329 can be formed by a stack of multipole elements, and the focusing control unit 807 is configured to drive each multi-pole element with an offset voltage to generate a lens function and with a plurality of additional individual voltages which are configured to scanning deflect the ion beam 103 and to compensate aberrations of the ion beam 103.

The source control module 801 is configured for a precise control of an ion beam current down to currents below few pA, for example below 1 pA, or even below 0.1 pA. With the source control module 801, it is further possible to select and adjust ion species during use. According to the disclosure, the repair system 1 is using a gas field ion source (GFIS) with Neon 343 and Helium 345 for circuit edit or repair operation. In an example, the repair system 1 is configured for using Neon ions for milling and imaging. The source control module 801 is configured for supplying Neon 343 by opening precision valve 347.1 inti the source chamber 351 and for providing a source voltage VS to the source tip 1. The repair system 1 according to the first embodiment is configured for exploiting the advantages of using Neon ions:
e) The repair system 1 according to the first embodiment is configured for a higher SE yield and a high lateral resolution

The neon ion beam arises from the gas field ion source 349, which is characterized by a small source size and a low energy spread, thereby allowing the ion beam 103 to be focused to a smaller size of the probe spot 105 of below 3 nm or less, 2.5 nm or less, 2 nm or less, or even 1.5 nm or less. Furthermore, Neon ions provide a high Secondary Electron Yield (SE Yield) and a noise level in the SE signal obtained by detector 331 is reduced. With secondary electron yield, the number of secondary electrons generated per interacting Neon ion is described. With a high SE Yield, the Neon ion beam current can be reduced for example by changing the aperture 317.2, or adjusting the crossover location 314, or a reduction of the Neon gas pressure by control of the precision valve 347.1.
f) The repair system 1 according to the first embodiment is configured for an imaging operation with a lower sputter rate

Generally, the sputter rate is proportional to the product of the ion beam current and the sputter yield. A low sputter rate is a parameter for determining the ability to see a feature before it is sputtered away, which is vital for edit and repair operations in semiconductor circuits or masks with many thin layers. It is important to understand that with ion beams, during imaging, there is always also a removal or sacrificing of a layer of a sample due to the sputtering activity related to the kinetic energy of the ions. With the significant lower mass of Neon, the sputter yield of Neon is about a factor of 2× or 3× less compared to the sputter yield of Gallium. In addition, as explained above, Neon provides a larger SE Yield, and can thus be operated with lower Neon Current or faster scanning frequencies compared to Gallium ions. Thereby, the unavoidable damage of the scanning area of a surface during ion beam imaging is reduced by Neon Ion beam imaging by a factor of 5× or even more. Thereby, the layer damage while imaging an area of a sample can be significantly reduced by a factor of 5× or even more.
g) The repair system 1 according to the first embodiment is configured for an operation with a lower ion beam current.

Further, the Neon beam is well suited to very low probe currents. Certain known Gallium Ion Beams are typically operated at currents about several nA, that is thousands of times larger beam currents than is typically used for the precision circuit edit or repair tasks. On the other hand, with the gas field ion source 349 and the control module 801, a repair system 1 according to the disclosure is configured for ion beam currents below 2 pA, below 1 pA, or even below 0.5 pA, and even lower currents can be realized with no further beam adjustments. Thereby, a milling rate can even further be reduced, and a high precision milling operation is possible as desired for precision circuit edit or repair operations. The repair system 1 is configured for a change of the ion beam current by adjusting the pressure of the supplied imaging gas (e.g. neon 343 or Helium 345) by the precision valves 347.1 or 347.2. Changing the pressure can be achieved over at least two orders of magnitude to make accessible probe currents from tens of pA (pico-Ampere) down to single digit fA (femto-Ampere). This type of change involves no change to aperture, beam alignment, focus, stigmation, etc. So, according to the disclosure, during use it is possible to adjust for example the ion beam 103 at for example 1 pA or 10 pA and then reduce the beam current by further reduction of the Neon 343 or Helium 345 by orders of magnitude by reducing the pressure in the gas field ion source 349. Thereby, a milling operation is further slowed down and a precision milling below 10 nm, below 5 nm or even less can be achieved. Thereby, the layer damage during ion beam scanning of an area of a sample can even further reduced by a factor of 10× or more. Thereby it is possible to mill or remove single layers within an integrated circuit or semiconductor mask, with layer thicknesses below 10 nm, 5 nm or even less.
h) The repair system 1 according to the first embodiment is configured for a repair or edit operation with a reduced damage to the integrated circuit at the repair site 41.

Neon is electrically insulating and will not change the electrical performance of insulating materials that are exposed to it. This allows the voltage contrast signatures, to be evident and used for endpoint detection. It also allows devices to be functioning while the milling proceeds. Any sample current signal remains unaffected by Neon ions. It has also been observed that Neon does not produce nanodots that are commonplace when milling with gallium in certain III-V materials.

With source control unit 801, the Neon ion beam energy can be adjusted below 10 keV, for example 6 keV, 5 keV, 4 keV, or 1 keV. Thereby, an ion implantation into large depths is reduced and a smoother surface is achieved during milling. With smoother surfaces, end-pointing of the Neon-milling is improved.
i) The repair system 1 according to the first embodiment is configured for a switching between a first ion beam with a first ion current and a second ion beam with a second ion current; the repair system 1 according to the first embodiment is further configured for a switching between different ion species for improved monitoring or even further reduced milling rates

During a milling and imaging step, the repair system 1 is configured to operate at low areal dosage of ions, for example one million ions per square micrometer or even less, for example 10.000 ions/μm\hat{ }2. Sufficient image quality is achieved with at least 10, 25 or 50 secondary electrons per image pixel. During a milling and imaging, the ion beam 103 can generate images of the sample with relatively little damage to the sample surface.

The repair system 1 according to the first embodiment of the disclosure is further configured to operate at one or more ion species in the ion beam 103. In an example, the repair system 1 is configured to work with a first ion species during a first mode of imaging and milling operation. The first ion species is for example Neon. The repair system 1 is further configured to work with a second ion species during a second mode of imaging and milling operation. The second ion species is for example Helium. In the source chamber 351, different gases can be provided with partial gas pressures adjusted by precision valves 347.1 and 347.2. During operation, the repair system 1 is configured to switch from a first gas to a second gas, for example from Neon 343 to Helium 345 and vice versa. In an example, the repair system 1 is configured to operate with a mixture of ions, for example Neon 343 and Helium 345. The ratio of the gas mixtures can be adjusted during operation by precision nozzles 347 in a wide range, for example 50:50 or 30:70 or 10:90 mixing ratio between the first and second ion species. Thereby, a SE yield and a sputtering rate can be further optimized for example depending on the material composition of a sample, and an even further reduction of a layer damage during ion beam scanning of an area of a sample can be achieved.

In a further example, the repair system 1 according to the first embodiment is further configured to supply at least one precursor gas during an ion beam operation. The sample comprising the multilayer structure is arranged within a sample chamber or process chamber 355, in which a gas nozzle 335 is arranged for the supply of the at least one precursor gas. The gas nozzle 335 is provided with a valve (not shown) and connected to at least one reservoir of precursor gases (not shown). Precursor gases are can comprise at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PM CPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, Formic acid, Formamide, A cetamide, N-methylacetamide, Propionyl Chloride, Propanioc acid, N,N-dimethylethanamide, Nitro acetic acid, Butyric acid, Lactic acid, and combinations thereof. With the addition of selected precursor gases, a homogeneity or uniformity of a milling operation is improved and a redeposition of milled material from the multilayer structure is reduced. Other selected precursor gases allow for insulating or conductive materials to be deposited by the ion beam.

With the repair system 1 according to the first embodiment, a layer damage during ion beam scanning of an area of a sample can be reduced by a factor of 10× and more, and an imaging or milling of single, thin layer with thickness below 10 nm, below 5 nm or even less is enabled. The improvement is achieved by configuration of the repair system 1 for performing during use an imaging and milling operation at reduced ion beam currents, wherein the repair system 1 is configured for a reduction of the ion beam current during use by a factor of 2 or 10 or more. The repair system 1 is further configured for using an ion species or ion species mixture selected according to predetermined SE yields and sputter rates for different material compositions. The repair system 1 is further configured with a gas field ion source 345 for generating an ion beam comprising Helium and/or Neon ions, providing high resolution imaging with resolution below 3 nm, below 2 nm or even less. According to a method of the second embodiment, it can be desirable to select an ion species for milling and imaging with a ratio of secondary electron yield (SEY) versus sputtering yield (SY) that is larger than 1. The ion beam species used during precision imaging and milling steps can have a SEY to SY-ratio of greater than 1, for example, 1.5, 2.0, or more. Table 1 summarizes SE yields, sputter yields and sputter rates at reasonable image acquisition at some typical examples. A reasonably image acquisition is for example reached with an SNR of about 5 or more. The precision milling and imaging steps can however comprise further ion species like Hydrogen, Argon or Xenon, for example.

TABLE 1

| | SE | Sputter | Ratio | Sputter rate: Depth sputter at | |
|---|---|---|---|---|---|
| Ion | Yield | Yield | SEY/SY | reasonable image acquisition | |
| Ga | 1.8 | 2.7 | 0.67 | 22 | nm |
| Ne | 2.34 | 1.4 | 1.7 | 8.5 | nm |
| He | 3 | 0.06 | 50 | <0.1 | nm |

The first task of a repair system 1 is to mill down through the various layers to expose the desired edit layer for the subsequent editing or repair operation. There is considerable importance in achieving the proper milled depth, since milling too deep could destroy the circuit in question or adjacent circuits, and too shallow a mill could make the modifications non-functional.

The repair system 1 according to the first embodiment is configured for a first mode of operation, during which higher ion beam currents are used and a second mode of operation, during which a second, lower ion beam current is used. In the second mode of operation, during which the source is switched to operate at the lower second ion currents, a source flickering is reduced, and the source current is generated with high stability. Thereby, end-pointing is further improved with the second mode of operation. In the first mode of operation, on the other hand, a faster milling speed can be achieved when a faster milling is possible, and an actual depth of a milled layer is well above the editing layer comprising the repair location. For example, the first mode of operation can be applied for the case when the milling depth is based upon “dead reckoning” is appropriate that is, based on time, or dosage. During the second mode of operation, a lower milling rate (e.g. in nanometers of depth per second, or cubic microns per minute) is achieved and a source current fluctuation is reduced. Thereby, the precision of an endpoint signal is increased.

The repair system 1 according to the first embodiment is configured for a first mode of operation, during which higher ion beam currents are used and a second mode of operation, during which a sputtering depth during a reasonable image acquisition is reduced. For example, a sputter depth during a reasonable image acquisition with an SNR of 5 or more is less than 10 nm, such as less than 8.5 nm, less than 8 nm, or even less than 5 nm. This is for example achieved by a mixture of Neon ions and Helium ions in the second ion beam.

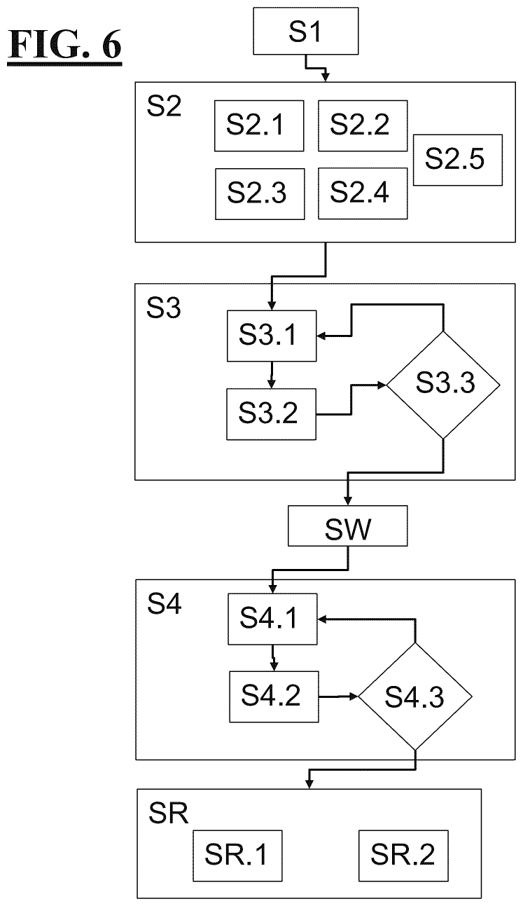

FIG. 6 illustrates a second embodiment of a repair method according to the disclosure. The explanation further refers to FIGS. 1 and 5 and reference is made to the description of FIGS. 1 and 5. The method comprises a determination of the instantaneous milled depth, ZA, relative to the depth, ZD, where the milling process should be stopped to access the edit layer 75.E which contains the circuit components to be edited. Information about the instantaneous milled depth ZA can be inferred from a secondary electron signal that is generated as the ion beam mills progressively deeper into the layers of materials. Certain changes in that signal, can indicate the current milled depth. A history of these changes can indicate that the desired depth has been attained, and the milling can stop, which is the so called “end-point” of the milling process. According to the second embodiment, the method comprises an iterative approach for milling and end-pointing with a first and a second ion beam current.

The second embodiment of the disclosure thus provides an improved method of ion-beam milling of a deep trench through a multilayer structure with precision end-pointing at a transition to a predetermined deep layer. The method comprises the steps of performing a first mode of fast milling to a first end-point. During the first mode of fast milling, a first ion beam with a first ion beam current is used. The first ion beam comprises at least a first ion species, at a certain beam energy, with a certain raster pattern, and may include use of a certain configuration of a gas injection system. The method further comprises the step of switching, when a first milling depth is reached, to a second mode of precision milling, and the step performing a second mode of precision milling until reaching a second end-point. The second endpoint can be corresponding to the transition to the predetermined deep layer. During the second mode of precision milling, a second ion beam with a second ion beam current is used. This may include a different beam species, different beam energy, or a different raster pattern, or a different use of the gas injection system. During the second mode of precision milling the rate of material removal or sputter rate (e.g. in nm/s or nm\hat{ }3/s) is substantially reduced by for example 2×, 3×, 4× or more relative to the first mode. For example, during the second mode of precision milling, a ratio of a yield of secondary charged particles SEY with a sputtering yield SY of a multilayer material of the multilayer structure is larger than 1, SEY/SY>1, for example SEY/SY>1.5, or even for example SEY/SY>2 or 3. For example, during the second mode of precision milling, Neon ions or a mixture of Neon ions with Helium ions are used.

In a first step S1, a sample 7 is loaded on a sample stage 500 of a repair system 1 and a repair instruction for a repair operation at a repair location 81 is determined. The sample 7 might be a processed semiconductor wafer, or a wafer die, or a wire bonded chip, or a chip with no wire bonding, or a built-up stack of chips, or a semiconductor mask. The sample 7 is registered by a coarse alignment using existing alignment marks or fiducials, and repair site 41 is aligned with respect to repair system 1. Depending on available fiducials, the repair site 41 is determined with lower accuracy during step S1.

The repair instruction typically comprises a target depth ZD of the edit layer 75.E. comprising the repair location 81, which is based on design information or a failure analysis. The repair instruction comprises the lateral location in (x,y)-coordinates of the repair location 81 and information about the layer stack to be removed from the sample surface to reveal the repair layer 75.E comprising the defect to be repaired or edited.

In step S2, the first layer surface 19 of a first layer 75.1 of the sample 7 is exposed. The exposure can be performed by a first, fast milling step S2.1 by any of the methods described above. Thereby, a first trench 43 is created at the repair site 41 and a first surface 15 within the bulk material 73 is exposed. In step S2.2, a more precise registration of the actual repair location 81 is performed. In an example, a first precision milling operation is performed to expose alignment fiducials 51, which are present on the surface 19 of the first layer 75.1. Typically, alignment fiducials 51 are generated during the fabrication of a semiconductor circuit and the position of alignment fiducials 51 is known from CAD data. The first precision milling is performed by a Neon ion beam 103 with a reduced ion beam current. With the alignment fiducials 51, a more precise registration of the integrated circuit can be performed and a more precise determination of the repair location 81 is achieved. After step S2.2, a repair location 81 can for example be determined with an accuracy below 200 nm or even less.

In step S2.3, a second trench 47 is milled by a second precision milling operation to expose a smaller area of the surface 19 of the first layer 75.1. With the more precise determination of the repair location 81, the second trench 47 can be milled with a smaller area compared to the first trench 43. The second precision milling is performed for example by a second ion beam 103.2 with a reduced ion beam current.

In some examples, the exposed surface 19 comprises semiconductor features, which can be compared to CAD information and allow for a further precision alignment of the integrated circuit structures below.

In step S2.4, additional alignment fiducials 33 can be generated either on the second surface 17 within the bulk material 73 or on the exposed surface 19. The additional alignment fiducials 33 can be positioned closer to the repair location 81 and allow for a smaller image field of view during control of the milling operation.

In order to acquire a high precision image of the surface 19 or the alignment fiducials 33, 51 without causing damage to the surface 19 or the alignment fiducials 33 and 51, an image acquisition step S2.5 can be performed and repeated throughout the method with a supply of Helium gas via a precision nozzle 347.2 to the ion beam 103 and a reduction of the Neon gas in the source volume 351 by restricting the precision valve 347.1 for the Neon gas supply. Thereby, a sputtering yield is reduced, and a secondary electron yield is increased.

In step S3, a first deep trench 47.1 is milled up to a predetermined depth ZC. The predetermined depth ZC is determined for example in Step S1, and ZC is selected depending on the layers 75.i and layer composition above the edit layer 75.E comprising the repair location 81. Typically, the predetermined depth ZC is selected approximately less than 50 nm, less than 30 nm, less than 20 nm or even less than 10 nm above the depth ZD of the edit layer 75.E.

In an example, a milling step S3.1 is performed by ion beam milling with a Neon ion beam 103 at a first beam current, a first beam energy, a first raster pattern, and an optional use of a first etch enhancement gas The first ion species is however not limited to Neon and can be given by other ions or atoms with mass number below 40, for example Argon, Chorine, Fluorine or Ammonium.

The method according to the second embodiment comprises the step S3.2 of determining an actual milling depth ZA during performing the first mode of fast milling step S3. From the actual milling depth ZA, it is determined whether approximately the first end-point ZC is reached. During or after a milling step S3.1, a secondary electron (SE) signal is analyzed and an actual depth ZA of the actually milled surface 117 is determined in step S3.2. The actual depth ZA is compared to the predetermined depth ZC in step S3.3. If the actual depth ZA is not exceeding the predetermined depth ZC, milling and imaging step S3.1 is repeated.

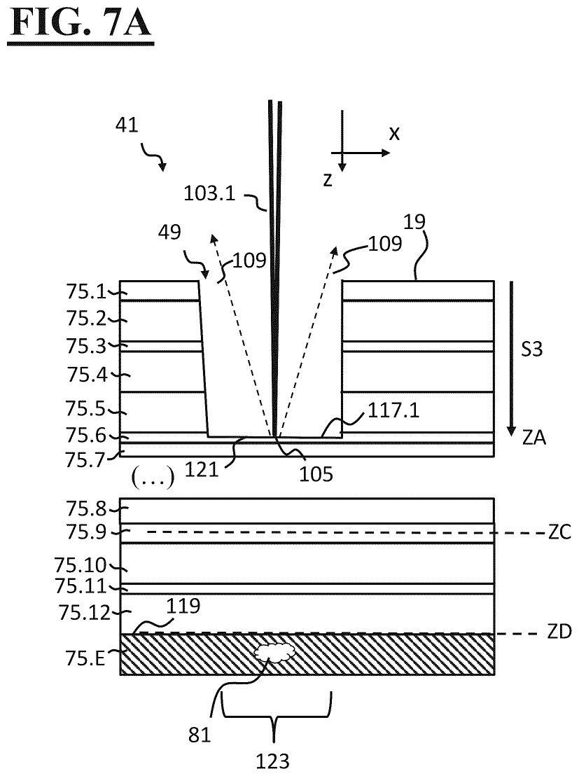

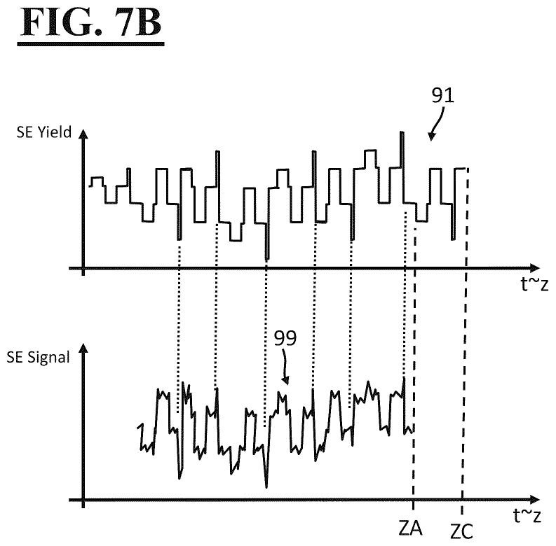

The step 3.2 of determining the actual depth ZA can be accomplished by tracking and accumulating the SE-signal during milling. The SE yield also depends on the material composition of each layer, and therefore it is possible to determine the layer number of the actual depth ZA. An example is illustrated in FIG. 7A. A deep trench 49 is milled intro a stack of layers 75.1 to 75.E, where only E=13 layers are shown, but the layer number of the editing layer 75.E can be much larger (see FIG. 1). For example, the stack of layers can comprise N=100 or even more layers, and for example between layer 75.7 and layer 75.8, many other layers may be present (not shown in the figures). Thereby, during step S3 of fast milling, a deep multilayer stack until transition zone ZC can be milled very fast.

At the bottom of the trench 49, a surface 117.1 within layer 75.6 is exposed at an area 121. The neon beam 103 has a better beam profile compared to a gallium beam, and therefore the slope angle of the side surfaces is reduced. Typically, the beam profile for a GFIS beam is accurately described as a gaussian beam with about 50% of the probe current within 3 nm diameter. The current density at a distance of 15 nm from the beam maximum is 100 times reduced. FIG. 7A shows the situation of ion beam milling with the Neon ion beam 103.1 after several iterations within step S3, where the actual depth ZA is well above the predetermined depth ZC. In this example, the actual layer is determined to be layer 75.6.

According to an example of step S3.2, the SE signal used for end-pointing is exclusively acquired in a subregion 123 of a milled surface of the deep milled trench. A SE signal collection of secondary electrons can be limited to a smaller region or center area 123, which is smaller compared to the exposed surface area 121. Thereby, a reduced collection efficiency of secondary electrons at the edges of the trench 49 is excluded. Thereby, the SE signal generated at the edge of the deep trench 49 can be excluded since it is often subject to fluctuations associated with the shallower collection efficiency, the trench wall, or drift artifacts.

It is an advantage of an example according to the second embodiment that during the precision milling step S3.1, the SE yield is improved at much lower sputtering rates and thus a precision end-pointing with an accuracy below 20 nm, below 15 nm or even below 10 nm is possible during milling. In part, this advantage arises because Neon has a larger secondary electron yield combined with a lower sputter rate. For Neon ions, the sputtered depth during an acquisition of a reasonable SE signal for depth determination is below 10 nm even at larger depths of a deep trench 49. Therefore, a Neon ion beam will provide a stopping distance that is more accurate than 20 nm, 15 nm, 10 nm, or even less, even at larger depths of the deep trench 49.

In an example of step S3.2, the step of determining the actual depth ZA comprises determining an integrated milling dose during the first mode of fast milling and comparing the integrated milling dose to a predetermined milling dose for the stack of multilayers. The predetermined milling dose used to mill down to a specific depth depends on the size and position of milling area, the number of dwell points and dwell time during the fast milling according the first milling mode of step S3.1, and the material composition of the layers milled at each milling depth. The predetermined milling dose is thus determined from a sequence of layer thicknesses and material compositions of the multilayer structure within milled area. The layer thicknesses and material compositions of the multilayer structure can be obtained from CAD information of the multilayer structure. The integrated milling dose is compared to the predetermined milling dose and an actual depth is estimated from the comparison.

In an example, the step of determining the actual depth comprises determining an area-integrated SE signal during the first mode of fast milling and comparing the area-integrated SE signal to a predetermined SE signal or expected SE yield for the stack of multilayers. The predetermined SE signal or expected SE yield can be computed from layer thicknesses and material composition within milled area. The layer thicknesses and material composition within milled area can be obtained from CAD information of the multilayer structure. In an example, the area-integrated SE signal is collected from a reduced area of a milling area within the deep trench.

An example of an SE signal is illustrated in FIG. 7B. From CAD data, an expected SE yield 91 obtained by milling with the first ion beam is computed for the given first ion beam current with expected milling time (upper curve). The expected SE yield depends on the milling speed, i.e. the milling area, the number of dwell points and dwell time during the fast milling according the first milling mode of step S3.1, and the material composition of the layers milled at a certain milling depth, as obtained for example from CAD data. The milling time t correlates with the milling depth z via the same parameters, i.e. milling area, the number of dwell points and dwell time during the fast milling according the first milling mode of step S3.1, and the material composition of the layers milled at a certain milling depth. The obtained accumulated SE signal 99 obtained during fast milling (lower curve) is compared to the expected SE yield 91, and the actual depth ZA is determined for example by computation of the minimum difference or by correlation of both curves. It is evident that not every layer transition can be detected from the SE yield 99, and the SE yield 99 provides more a quantified indicator about an approximate milling depth of an actual milling depth ZA.

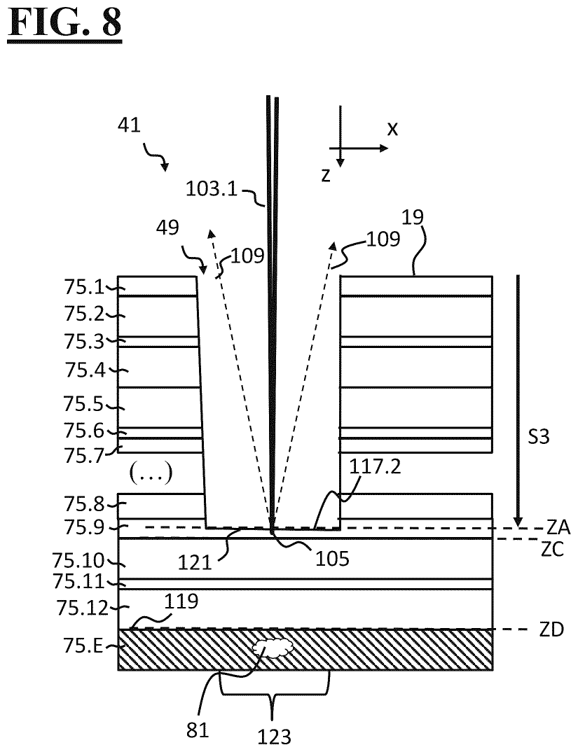

A milling step S3.1 at a first beam current is performed until the predetermined depth ZC is reached approximately. This situation is illustrated in FIG. 8, where the actual depth ZA of the exposed surface 117.2 is approximately at the predetermined depth ZC. With approximately reaching of milling depth ZC it is meant that the difference of the actual milling depth ZA and the predetermined milling depth ZC is less than the milling thickness of about five fast milling or image acquisition operations. As explained above, even an image acquisition with an ion beam is accompanied by a milling as well, depending on the sputter yield of the ion beam during imaging.

When the predetermined depth ZC is approximately reached, the repair system is switched in step SW from the first mode of fast milling to a second mode of precision milling with even higher precision. The method continues then with step S4. A precision milling and imaging step S4.1 is performed by precision milling with a second ion beam 103 at a second beam current.

In a first example, the second ion beam is again comprising Neon ions and the second beam current is lower compared to the first beam current, thereby a milling rate during the precision milling and imaging step S4.1 is reduced. A reduction in a current of Neon ions is achieved during step SW by adjusting a precision valve 347.1 to control a Neon gas pressure in the gas field ion source chamber 351. As a result, the second ion beam comprises the first ion species with reduced ion dose or volume concentration of first ion species in the second ion beam.

In a second example, the precision milling and imaging step S4.1 is performed with a second ion beam comprising different ion species, for example comprising Helium-ions. Different gases are provided in step SW by adjusting the precision valves 347.1 and 347.2 to control a plurality of partial gas pressures in the gas field ion source chamber 351. In an example of step SW, the precision milling and imaging step S4.1 and end-pointing is improved by switching the gas in the source chamber 351 for example to Helium such that the ion beam 103 comprises Helium ions. With helium ions, even lower sputter rates of for example about 40× lower compared to Neon can be achieved while a considerable number of secondary electrons is generated. With Helium-ions, a high-resolution imaging with resolution of below 1 nm, below 0.75 nm, below 0.5 nm, for example 0.3 nm can be achieved with minimum damage to a sample surface. In an example, the step SW of switching to the second mode of precision milling further comprises the step of reducing a gas delivery of a first ion species to an ion-beam source.

In a third example, during the precision milling and imaging step S4.1, the second ion beam is scanned with a second scanning frequency over a surface area of the trench, wherein the second scanning frequency is larger compared to a first scanning frequency. The first scanning frequency is used during the first mode of fast milling in step S3.1, during which the first ion beam is scanned over a surface area of the trench.

Thereby, with each example, during the second mode of precision milling the rate of material removal or sputter rate is substantially reduced by for example 2×, 3×, 4× or more relative to the first mode. During the second mode of operation, a sputtering depth during a reasonable image acquisition is reduced. For example, during a reasonable image acquisition with an SNR of 5 or more during the second mode of operation, a sputter depth is less than 10 nm, such as less than 8.5 nm, less than 8 nm, or even less than 5 nm. This is for example achieved by a mixture of Neon ions and Helium ions in the second ion beam.

After each milling and imaging step S4.1, a secondary electron signal is analyzed and an actual depth ZA of the actually milled surface 117 is determined in step S4.2. The actual depth ZA is compared to the depth ZD in step S4.3. If the actual depth ZA is not exceeding the depth ZD or the repair layer 75.E, precision milling and imaging step S4.1 is repeated.

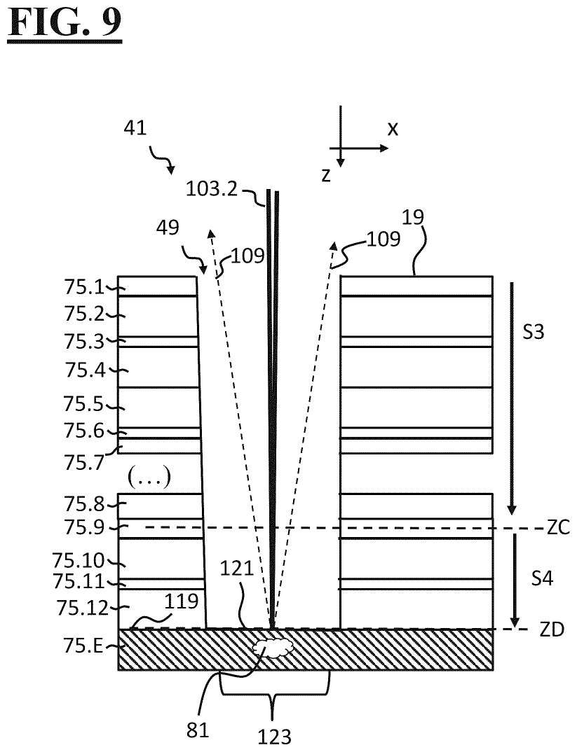

If during the analysis of step S4.2 it is determined that the surface of the edit layer 75.E has been reached, the precision milling and imaging step S4.1 is stopped. This situation is illustrated in FIG. 9, where the repeated milling and imaging step S4.1 with the second ion beam 103.2 has reached the surface 119 or edit layer 75.E.

In an example of the depth determination Step S4.2, the end-pointing is achieved by a digital image generated during the precision milling and imaging step S4.1. During the precision milling and imaging step S4.1, the repair system 1 according to the disclosure is configured for obtaining an image of an area of the actual surface 117 of the sample 7. The second ion beam 103.3 is progressively scanned over the actual surface 117, and a pixelated image of the region of the surface 117 of the actual layer 75.i is generated by assigning each pixel a grey level that is related to the signal of secondary electrons that are generated at the surface 117 of the sample 7. Each the layer 75.1 to 75.E is typically patterned as part of the semiconductor layout. Each layer comprises therefore different semiconductor features, such as vias, interconnections, nodes, gates or the like. With the second ion beam 103.2, during the milling operation, a high-resolution digital image of the milled area 121 is obtained, comprising regions of different brightness according to different semiconductor features of different materials within the layers. With the larger SE yield and smaller spot size of the second ion beam 103, high quality images can be ascertained during a milling operation and for example patterns or semiconductor features can be discriminated during the milling operation. Thereby, an unambiguous determination of the current milling depth is provided. As the ion beam 103.2 progressively mills deeper and deeper, the pattern associated with each layer changes and serves as an unambiguous indication of the current milling depth ZA.

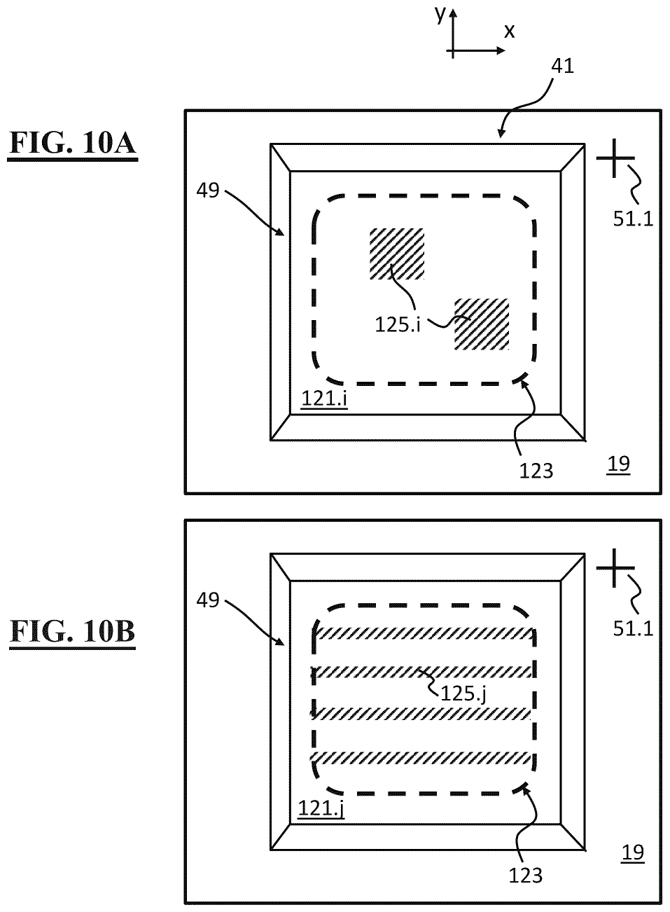

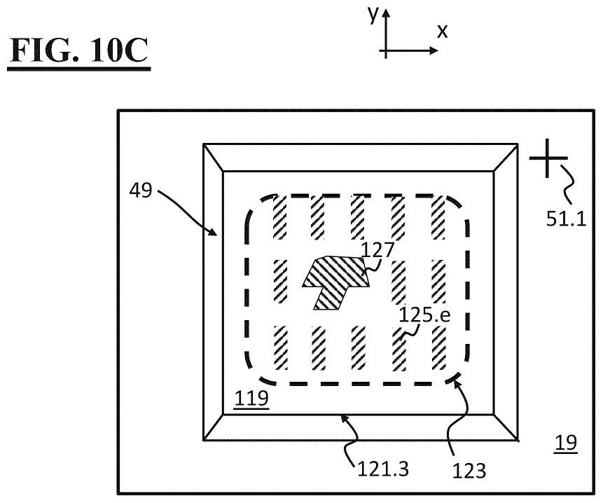

A method step S4.2 can thus comprise pattern detection and a comparison to CAD information for precision control of milling of deep trenches. FIGS. 10A-10C illustrate an example. FIG. 10A shows a digital image of a first milled area 121.i during the milling of the deep trench 49. A registration of the semiconductor is achieved with alignment mark or fiducial 51.1. In an example, the alignment mark 51.1 can also be given by a semiconductor feature visible the surface 19 of the first layer 75.1. During milling, a first digital image of center area 123 of the first milled area 121.i is obtained, wherein the digital image comprises the semiconductor features 125.i. The first digital image comprising features 125.i is compared to the CAD layout information about the design of the integrated semiconductor at the repair site 41, and the layer 75.i according to the actual depth of the first milled area 121.i is determined. The milling and parallel high-resolution image acquisition is continued until the next layer, where a second milled area 121.j is exposed, generating during imaging a digital image comprising the semiconductor features 125.j (see FIG. 10B). The semiconductor features 125.j are again compared to expected features according to CAD information, and the according layer 75.j is determined. In the example it is assumed that the layer 75.j is the lowest layer covering the layer 75.E comprising the defect to be repaired. The combined milling and high-resolution imaging is further slowed down by a further reduction of the milling rate, until the semiconductor features of the upper surface 119 of layer 75.E are detected (see FIG. 10C). The digital image obtained from surface 119 comprises the semiconductor features 125.e of the repair layer 75.E as well as a defect 127. With the small spot size available with the second ion beam 103.2, the small semiconductor features of present and future integrated circuits can be resolved. With the larger secondary electron yield generated by second ion beam 103.2, digital images with reasonable image quality of milled areas can be generated with high signal to noise ratio (SNR) and low damage to the actual semiconductor layer. A sufficient SNR is typically given by a SNR of about 5 or more. For example, to produce a useful image, more than 25 secondary electrons per pixel are used (SNR˜5). Thereby, a repair or edit operation of even tiny semiconductor features of below 5 nm, below 3 nm or even less in deep layers or certain other layers is possible.

In an example, pattern matching is applied in step 4.2 to the digital images obtained during ion beam milling. Pattern templates are derived from CAD data according to the expected depth of the actual milling step, and pattern templates are compared to digital images. Digital images can further be processed by image processing techniques, like noise reduction and edge extraction by morphologic operations. Thereby, an actual depth of an actual milling step can be determined with a precision below 5 nm or even less. In an example, especially suitable for repeated repair or edit operations, machine learning methods can be applied for the determination of actual depth of a digital image. Even more, machine learning methods like deep learning can be applied for a depth determination.

The method step S4 can further be improved by utilizing the known thickness of each of the layers 75.i within the stack of layers. The layer thickness of each layer 75.i is typically known from CAD data. In an alternative example, the layer thicknesses can be determined by a milling and imaging operation through the layer stack at a reference site of the sample 7. Thereby, a sputtering rate of a second ion beam 103.2 can be adjusted to a thickness of an actual layer above the edit layer 75.E.

Especially, the properties of the Neon or Helium ion beam are used to ascertain high quality image contrast and recognize patterns while milling each of these layers, which provides an unambiguous determination of a current milled depth and an unambiguous signal for end-pointing. The region to be milled can be a simple rectangle but can also involve complex shapes represented by a union or intersection. Since the repair site 41 likely has a defect 81 within it, it is also possible to mill a broader region, including consisting of two non-joined regions, and rely only upon the endpoint signal from the most relevant region, instead of the defect region which may have less useful end-pointing signal characteristics.

A gas field ion source is typically known to exhibit fluctuations in the emission. These fluctuations can occur at timescales from 10 ms to a few seconds. Longer time scale effects are often characterized as gradual dimming or brightening, or emission droop, and might be caused for example by temperature variations, effect of spurious emission sites, or gradual changes in the shape of the beam. The short term, more abrupt current fluctuations are problematic because the generated SE signals. However, with the reduced ion current in milling step S3.1 and with the even more reduced second ion beam current in milling step S4.1, a more stable emission is achieved.

In step SR, the repair process is performed. The repair process SR can comprise a removal of defect at repair location 81 in precision milling step SR.1 and a material deposition by ion beam assisted deposition step SR.2. Precision milling step SR.1 can be at the second beam current or an even lower beam current, wherein during the removal of defect material is limited to the area of the defect at repair location 81.

Milling step SR.1 and deposition step SR.2 are assisted by precursor molecules delivered broadly to the repair site 41, in conjunction with the finely focused ion beam 103 which activate the molecules in some way. Precursor molecules can be made available by the supply of a precursor gas, for example comprising of any of the precursor gases mentioned above. For the deposition of insulators, precursors might include for example, siloxane or PM CPS which will remain fixed and accumulate in the precise regions irradiated by the nanometer scale ion beam 103. Thus, insulating materials can be deposited in arbitrary patterns with nanometer precision. Similarly, conductive metal precursor gases such as W(CO)6 or (Co)2(CO)8, can be used to deposit electrical conductors using focused ion beam 103. According to the second embodiment of the disclosure, these repairs or editing operations according step SR are achieved without creating further damage to a semiconductor circuit. This is achieved by using instead of Gallium ions Neon or Helium ions in the ion beam 103, which do not change a conductivity of a semiconductor material. Thereby, deposited materials are expected to be in a purer form due to the usage of for example the Neon ion beam 103. Insulating layers deposited during step SR.2 as part of the circuit edit activities are 100 times more insulating compared to insulating layers generated with a Gallium ion beam.

The method according to the second embodiment is here described at the example of a first, fast milling step S3 and a second, precision milling step S4 with a switching step SW in between. The method is, however, not limited to two millings steps, but can comprise at least a further switching step SW 2 in analogy to first switching step SW and a further precision milling step S5 similar to step S4 with even more reduced milling rate.

A method according to the second embodiment can further be improved by several additional mechanisms. In a first example, the method further comprises the step of acquiring of a surface image of an actual milled surface at a not precisely known actual depth and determining the actual depth within the multilayer stack from the surface image. The step of determining the actual depth comprises a comparison of the surface image with CAD data. In an example, the step of determining the actual depth comprises at least one of an image processing, feature extraction, or pattern detection. In the example of step S4.2 given above, the step of acquiring of a surface image is performed during the second mode of precision milling. In a further example, the step of acquiring of a surface image of an actual milled surface comprises the step of switching the first or second ion beam to a third ion beam, wherein the third ion beam has a ratio of a yield of secondary charged particles SEY with a sputtering yield SY of a multilayer material of the multilayer structure larger than 10, or SEY/SY>10. With such a third ion beam, for example comprising a higher concentration of Helium ions, a surface image of the actually milled surface can be obtained with low sputtering, i.e. with low change to the actual depth. After the actual depth has been determined with large accuracy, the third ion beam is switched back to the first or second ion beam. An example of the method according to the second embodiment comprises therefore the second step SW 2 of switching to a third ion beam. The second step SW 2 comprises the step of changing a gas delivery to an ion-beam source to either add a third ion beam species to the first or second ion beam, and/or to reduce a gas delivery of an ion species to the first or second ion-beam. The third ion beam species can for example be Helium ions. In an example, the method further comprises the step of an adjustment of a milling area of subsequent milling operation to the edit location.

According to a second example of the further improvements, the method according to the second embodiment further comprises the step of forming an alignment fiducial 33 or 51 close to the position of the milling area. In the example, the fiducials 33 or 51 are also used for a drift compensation. During the milling and imaging operation with the ion beam in steps S3 and S4, a fiducial can frequently be imaged according to step S2.5 at low milling rate and without generating any damage to the sample 7. The fiducials are tolerant to repeated imaging with the ion beam of step 2.5. The position of the milling area is generally determined with respect to the edit location. According to an example, the method of the second embodiment further comprises the step of acquiring a surface image of an alignment fiducial, the step of performing an alignment step of the position of the milling area of the deep trench, and the step of continuing the milling operation according to the first or second mode of milling. The alignment method is, however not limited to the fiducial 33. Within the exposed region of surface 19 are also exposed CAD design features which serve as navigational references for the ion beam placement. According to an example, an adjustment of the position of milling area is determined from CAD information of the multilayer structure, which is compared to a surface image of a milled area, with the surface image either obtained by the second ion beam during step S4.2 or with the third ion beam.

Based upon the first image of the registration site, any relative offset observed during step S3 or step S4 can be used to compensate any offset of the ion beam as the deep milling and circuit edit progress continues. With the frequent monitoring and realignment at for example fiducial 33 or of CAD features present at the repair site 41 and visible in the trench 47 at surface 19, a drift of the repair system can be compensated by either an offset to the internal beam deflector or a stage movement. The step of performing an alignment can therefore comprise a step of driving at least one precision actuator of a sample stage for holding the multilayer structure. In another example or in addition, the step of performing an alignment can comprise a precision voltage supply to an ion beam deflector for scanning the ion beam. In an example the method according to the second embodiment therefore comprising the step of performing drift monitoring of a position of the multilayer structure with respect to an ion beam axis and the step of performing a drift compensation during first or second mode of operation. The step of performing of the drift compensation can further comprise a steps of computing compensation signals and providing the compensation signal to short stroke control electronics to generate at least one of a control signal of a sample stage or an ion beam deflector.

According to a third example of the further improvements, a charge neutralization scheme is implemented to reduce charging effect and to reduce undesired charging artifacts especially of insulating materials. Generally, a neutralization scheme is operating in an alternating fashion with the ion beam activities. A neutralization scheme can be comprising an exposure with an electron flood gun, local gas flow, or photon induced electrons. For example, ion beam milling is performed for 500 μsec, then an electron flood gun is operated for 200 μsec, and this process is repeated.

According to a fourth example of the further improvements, a voltage contrast generated by charging of the sample surface is utilized to provide useful information about the electrical properties of the sample, such as resistance, capacitance, and network connectivity. For example, an electron flood gun can be utilized not only to neutralize for example neon ions according to the fifth example but may also serve as a mechanism to pre-charge the semiconductor features present at the repair site 41. For example, if a conducting semiconductor feature in a layer is connected to a conducting periphery, a charge may not be accumulated in the feature. A disconnected semiconductor feature, however, will build up and keep a charged induced by either secondary electron emission or by charging with a flood gun. Further, using neon ions for imaging, active voltage contrast techniques can be utilized by driving electrical signal through the chip during the circuit editing steps.

According to a fifth example of the further improvements, precursor gases as listed above may be used in combination with the ion beam milling. A variety of known precursors gases comprises amine, acetate, iodine, chlorine, fluorine, water vapor, ozone, and the like. The precursor gases help to volatilize the sputtered material and reduce redeposition effects. Thereby, more vertical sidewalls of a deep trench 49 (e.g. more than 80 degrees, more 85 degrees, more than 88° or close to 90°) can be achieved. Precursor gases may be supplied via the gas nozzle 335, and the method according to the second embodiment may include steps to control valves of the precursor supply nozzles 335 during performance of steps S3 or S4.

The disclosure provides a method of operation of a focused ion beam system and a focused ion beam system with a control operator with a processor and a memory and software installed, configured to provide a fast and precise circuit edit operation for thick multilayer structures. Thick multilayer structures are present in recent semiconductor integrated circuits, fabricated on semiconductor wafers, and are comprising a large number N of layers with up to N=100 or more layers. The layer thickness of a certain layer may be below 20 nm, below 10 nm or even less, and thus below the sputter rate achievable with a conventional Gallium FIB during a single imaging operation. The disclosure enables precision sputtering and end-pointing of thin layers with thicknesses below 20 nm, below 10 nm or even less. With a ratio or secondary electron yield SEY to sputtering yield SY, SEY/SY, larger or equal to 1, or SEY/SY>1, a precise milling of deep thin layers is achieved during the disclosed precision milling without unnecessary damage to the deep thin layers of layer thicknesses below 20 nm. With a further increased ratio or secondary electron yield SEY to sputtering yield SY, SEY/SY, larger or equal to 2, or SEY/SY>2 or even more, for example 10, a milling rate during an image generation for precision end-pointing is further reduced, and it is possible to perform an end-pointing of thin layers with layer thicknesses below 10 nm, below 8 nm or even less. The disclosure is not limited to the embodiments and examples, but also comprises variations, combinations, or modifications thereof. Other embodiments of the disclosure will be apparent to those skilled in the art from consideration of the specification and practice of the disclosure disclosed herein. The disclosure is further described in following clauses:
Clause 1: Method of ion-beam milling of a deep trench through a multilayer structure with precision end-pointing at a transition to a predetermined deep layer, comprising the steps of:
   performing a first mode of fast milling to a first end-point,
   switching, when the first milling depth is reached, to a second mode of precision milling,
   performing a second mode of precision milling until reaching a second end-point.
Clause 2: The method according to clause 1, further comprising
   performing a repair operation in the predetermined deep layer.
Clause 3: The method according to clause 1 or 2, wherein the second endpoint is corresponding to the transition to the predetermined deep layer.
Clause 4: The method according to any of the clauses 1 to 3, wherein
   during the first mode of fast milling, a first ion beam with a first ion beam current is used, the first ion beam comprising at least a first ion species and
   during the second mode of precision milling, a second ion beam with a second ion beam current is used, and wherein
   during the second mode of precision milling, a ratio of a yield of secondary charged particles SEY with a sputtering yield SY of a multilayer material of the multilayer structure is larger or equal to 1, or SEY/SY>=1.
Clause 5: The method according to any of the clauses 1 to 4, wherein
   during the first mode of fast milling, a first ion beam with a first ion beam current is used, the first ion beam comprising at least a first ion species and
   during the second mode of precision milling, a second ion beam with a second ion beam current is used, and wherein
   during the second mode of precision milling, a second sputter rate is at least 2× slower than a first sputter rate in the first mode.
Clause 6: The method according to clause 4 or 5, wherein the second ion beam current is lower compared to the first ion beam current.
Clause 7: The method according to any of the clauses 4 to 6, wherein the second ion beam comprises the first ion species with reduced ion dose.
Clause 8: The method according to any of the clauses 4 to 7, wherein during the second mode of precision milling, a sputter depth during a reasonable image acquisition with an SNR of 5 or more is less than 10 nm, such as less than 8.5 nm or even less than 8 nm.
Clause 9: The method according to any of the clauses 4 to 8, wherein the step of switching to the second mode of precision milling further comprises the step of reducing a gas delivery of a first ion species to an ion-beam source.
Clause 10: The method according to any of the clauses 4 to 9, wherein the first ion species has a mass number below 40.
Clause 11: The method according to clause 10, wherein the first ion species is Neon.
Clause 12: The method according to any of the clauses 4 to 9, wherein the second ion beam comprises a second ion beam species, the method further comprising the step of changing, during the step of switching to the second mode, a gas delivery to an ion-beam source to add the second ion beam species to the second ion beam.
Clause 13: The method according to clause 12, wherein the second ion beam species is Helium.
Clause 14: The method according to clause 12 or 13, wherein the step of switching to the second mode of precision milling further comprises the step of reducing a gas delivery of a first ion species to an ion-beam source.
Clause 15: The method according to any of the clauses 1 to 14, wherein
   during the first mode of fast milling, a first ion beam is scanned with a first scanning frequency over a surface area of the trench, and
   during the second mode of precision milling, a second ion beam is scanned with a second scanning frequency over a surface area of the trench, wherein the second scanning frequency is larger compared to the first scanning frequency.
Clause 16: The method according to any of the clauses 1 to 15, wherein the step of performing the first mode of fast milling to the first end-point comprises the steps of
   determining an actual milling depth during performing the first mode of fast milling;
   determining whether the actual milling depth is approximately corresponding to the first end-point.
Clause 17: The method according to clause 16, wherein the step of determining the actual depth comprises determining an integrated milling dose during the first mode of fast milling and comparing the integrated milling dose to a predetermined milling dose for the stack of multilayers.
Clause 18: The method according to clause 17, wherein the predetermined milling dose is determined from a sequence of layer thicknesses and material compositions of the multilayer structure within milled area.
Clause 19: The method according to clause 18, wherein the predetermined milling dose is computed from CAD information of the multilayer structure.
Clause 20: The method according to clause 16, wherein the step of determining the actual depth comprises determining an area-integrated SE signal during the first mode of fast milling and comparing the area-integrated SE signal to a predetermined SE signal for the stack of multilayers.
Clause 21: The method according to clause 20, wherein the predetermined SE signal is computed from layer thicknesses and material composition within milled area.
Clause 22: The method according to clause 20 or 21, wherein the predetermined SE signal is computed from CAD information of the multilayer structure.
Clause 23: The method according to clause 20, wherein the area-integrated SE signal is collected from a reduced area of a milling area within the deep trench.
Clause 24: The method according to any of the clauses 1 to 23, further comprising the steps of
   acquiring of a surface image of an actual milled surface at an actual depth,
   determining the actual depth within the multilayer stack from the surface image.
Clause 25: The method according to clause 24, wherein the step of determining comprises a comparison of the surface image with CAD data.
Clause 26: The method according to clause 24 or 25, wherein the step of determining comprises at least one of an image processing, feature extraction, or pattern detection.
Clause 27: The method according to any of the clauses 24 to 26, wherein the step of acquiring of a surface image is performed during the second mode of precision milling.
Clause 28: The method according to any of the clauses 24 to 27, further characterized by
   switching the first or second ion beam to a third ion beam, wherein the third ion beam has a ratio of a yield of secondary charged particles SEY with a sputtering yield SY of a multilayer material of the multilayer structure larger than 10, or SEY/SY>10, and
   acquiring of the surface image of the actual milled surface with the third ion beam, and
   switching the third ion beam back to the first or second ion beam.
Clause 29: The method according to clause 28, wherein the step of switching to the third ion beam comprises the step of changing a gas delivery to an ion-beam source to either add a third ion beam species to the first or second ion beam, and/or to reduce a gas delivery of an ion species to the first or second ion-beam.
Clause 30: The method according to any of the clauses 24 to 29, further comprising the step of an adjustment, based on the surface image, of a milling area of subsequent milling operation to an edit location.
Clause 31: The method according to clause 30, wherein the step of adjustment of the milling area is performed according to CAD information.
Clause 32: The method according to any of the clauses 1 to 31, further comprising the step of determining a position of a milling area of the deep trench to be milled with respect to an edit location.
Clause 33: The method according to any of the clauses 1 to 32, further comprising
   acquiring a surface image of an alignment fiducial,
   performing an alignment step of the position of the milling area of the deep trench,
   continuing the milling operation according to the first or second mode of operation.
Clause 34: The method according to any of the clauses 1 to 33, further comprising the step of forming an alignment fiducial close to the position of the milling area.
Clause 35: The method according to clause 32, wherein the position of the milling area is determined from CAD information of the multilayer structure.
Clause 36: The method according to clause 33, wherein the step of performing an alignment comprises a step of driving at least one of a precision actuator of a sample stage for holding the multilayer structure or a precision voltage supply to an ion beam deflector for scanning the ion beam.
Clause 37: The method according to any of the clauses 1 to 36, further comprising the steps of
   performing drift monitoring of a position of the multilayer structure with respect to an ion beam axis; and
   performing a drift compensation during first or second mode of operation.
Clause 38: The method according to clause 37, wherein the step of performing of the drift compensation further comprises the steps of computing compensation signals and providing the compensation signal to short stroke control electronics to generate at least one of a control signal of a sample stage or an ion beam deflector.
Clause 39: The method according to any of the clauses 1 to 38, further comprising the step of providing a precursor gas to a sample chamber for chemically assisting an ion beam milling or repair of the multilayer structure during the first or second mode of operation.
Clause 40: The method according to clause 39, wherein the precursor gas comprises at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PM CPS, Tungsten Hexacarbonyl, Water, Xenon Difluoride, methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, Formic acid, Formamide, A cetamide, N-methylacetamide, Propionyl Chloride, Propanioc acid, N,N-dimethylethanamide, Nitro acetic acid, Butyric acid, Lactic acid, and combinations thereof.
Clause 41: A focused ion beam system with a control operator with a processor and a memory and software installed, configured to perform the method of any of the clauses 1 to 40.
Clause 42: A repair system for editing a multilayer structure, comprising
   a gas field ion source for generating an ion beam, comprising at least two gas nozzles connected via at least two precision valves for providing different source gases to the gas field ion source,
   an ion beam column, and
   a sample enclosure, comprising a sample stage for holding a sample comprising the multilayer structure and a detector configured to attract interaction products generated during us by interaction of the ion beam with a sample,
   an operation control unit, configured for controlling components of the repair system, the operation control unit comprising:
   an image acquisition control unit connected the detector,
   a source control module for controlling during use a source operation of the gas field ion source, source control module being connected to the at least two precision valves for adjusting a source gas concentration,
   wherein the source control module is configured for selecting and adjusting during use an ion beam current of a first ion species.
Clause 43: The repair system according to clause 42, wherein the first ion species is Neon.
Clause 44: The repair system according to clause 42 or 43, configured for providing and adjusting during use ion beam currents of two or more different ion beam species.
Clause 45: The repair system according to clause 44, wherein a second ion species is Helium.
Clause 46: The repair system according to clause 44, wherein a second ion species comprises at least an ion species with atomic mass number below 40.
Clause 47: The repair system according to any of the clauses 42 to 46, wherein the source control module is configured to adjust during use the ion beam current to achieve a low areal dosage of ions of below one million ions per square micrometer or even less, for example 10.000 ions/μm\hat{ }2.
Clause 48: The repair system according to any of the clauses 42 to 47, wherein the source control module is configured to adjust during use an ion beam current down to currents below few pA, for example below 1 pA, or even below 0.1 pA.
Clause 49: The repair system according to any of the clauses 42 to 48, wherein the source control module is further configured to adjust during use a kinetic energy of an ion beam to below 10 keV, for example 6 keV, 5 keV, 4 keV, or 1 keV.
Clause 50: The repair system according to any of the clauses 42 to 49, wherein the source control module is further configured to adjust during use a lower sputter rate with a ratio of a secondary electron yield SEY to sputter yield SY of larger than 1, for example SEY/SY=1.5 or even more.
Clause 51: The repair system according to clause 50, further configured for a switching during use between ion species for improved monitoring at further reduced milling rates, for example with a SEY/SY=10 or more.
Clause 52: The repair system according to any of the clauses 42 to 51, further configured for a switching during use between a first ion beam with a first ion current and a second ion beam with a second ion current.
Clause 53: The repair system according to any of the clauses 42 to 52, configured for switching during use from a first ion beam during a first mode of milling operation to a second ion beam comprising a second ion species during a second mode of milling operation.
Clause 54: The repair system according to clause 53, wherein the second ion species is Helium.
Clause 55: The repair system according to any of the clauses 42 to 54, configured to operate with a mixture of ions of a first and a second ion species, wherein the source control module is configured to adjust during use a gas mixing ration by precision nozzles in a range of 50:50 or 30:70 or 10:90 mixing ratio between the first and second ion species.
Clause 56: The repair system according to any of the clauses 42 to 55, further comprising a gas nozzle arranged in the sample enclosure, configured for providing during use a supply of at least one precursor gas.
Clause 57: The repair system according to clause 56, wherein the at least one precursor gas comprises at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PM CPS, Tungsten Hexacarbonyl, Water, Xenon Difluoride, methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, Formic acid, Formamide, A cetamide, N-methylacetamide, Propionyl Chloride, Propanioc acid, N,N-dimethylethanamide, Nitro acetic acid, Butyric acid, Lactic acid, or combinations thereof.
Clause 58: The repair system according to clause 56 or 57, wherein the at least one precursor gas comprises dicobalt octacarbonyl or molybdenum hexacarbonyl.
Clause 59: An ion beam system, comprising
   a gas field ion source for generating an ion beam, comprising at least one gas nozzle connected via a precision valve for providing a source gases to the gas field ion source,
   an ion beam column,
   an operation control unit, configured for controlling components of the ion beam system,
   an image acquisition control unit connected the detector,
   a sample enclosure, comprising a sample stage for holding a sample and a detector configured to attract interaction products generated during us by interaction of the ion beam with a sample, and
   a gas nozzle arranged in the sample enclosure, configured for providing during use a supply of a precursor gas comprising dicobalt octacarbonyl or molybdenum hexacarbonyl.

An improved system and method for circuit edit or repair within multilayer structures comprising a large number of layers including layers with thicknesses below 20 nm or even less, for example below 10 nm or 8 nm is provided. The system and method of operation is capable of an advanced end-pointing of a milling operation within the large number of layers, including of end-pointing of the thin layers without unnecessarily damaging the multilayer structure.

### LIST OF REFERENCE NUMBERS

1 Repair System
7 substrate
15 first surface
17 second surface
19 surface of first layer
33 alignment fiducial
41 repair site
43 first trench
45 trench at alignment fiducial
47 second trench
49 deep trench
51 alignment fiducial
71 bulk material
73 bulk material
75.1 . . . 75.N multi-layer stack
79 bulk material
81 repair location
91 Secondary electron yield
93 collection efficiency
95 charging effects
97 SE signal during milling
99 SE signal during milling according to the disclosure
103 Ion beam
105 focus point of ion beam
109 interaction product
117 surface within layer
119 surface of layer
121 milled area
123 center area
125 semiconductor feature
127 defect
301 Source tip
303 heating wire
305 Mounting posts
307 Extractor electrode
309 Condenser lens
311 first multipole element
313 second multipole element
314 intermediate focus
315 aperture stop carrier
317 aperture stops
319 Beam Blanker
321 Beam dump
323 third multipole element
325 fourth multipole element
327 fifth multipole element
329 objective lens
331 detector
333 interaction products
335 gas nozzle
337 precursor gas
339 calibration sample
341.1 source gas nozzles
343 first source gas
345 second source gas
347 precision valves
349 gas field ion source
351 source chamber
353 ion beam column
355 sample enclosure or sample chamber
359 column axis
500 sample stage
800 operation control unit
801 source control unit
803 image acquisition control unit
805 source gas control unit
807 focusing control unit

What is claimed is:

1. A method of ion-beam milling a deep trench through a multilayer structure to a deep layer, the method comprising:
a) fast ion-beam milling the multilayer structure to a first end-point in the multilayer structure;
b) when the first end-point in the multilayer structure is reached, switching to precision ion-beam milling; and
c) precision ion-beam milling the multilayer structure until reaching a second end-point in the multilayer structure.

2. The method according to claim 1, further comprising performing a repair operation in the predetermined deep layer.

3. The method according to claim 1, wherein the second endpoint corresponds to a transition in the multilayer structure to the predetermined deep layer.

4. The method according to claim 1, wherein:
a) comprises using a first ion beam having a first ion beam current;
b) comprises using a second ion beam having a second ion beam current; and
during b), a ratio of a yield of secondary charged particles to a sputtering yield of a multilayer material of the multilayer structure is at least one.

5. The method according to claim 1, wherein, during b), a sputter depth is less than 10 nanometers during an image acquisition with a signal to noise ratio of at least five.

6. The method according to claim 1, wherein:
a) comprises using a first ion beam having a first ion beam current and a first sputter rate;
b) comprises using a second ion beam having a second ion beam current and a second sputter rate; and
the second sputter rate is at least two times less than the first sputter rate.

7. The method according to claim 1, wherein:
a) comprises scanning a first ion beam with a first scanning frequency over a surface area of the trench;
b) comprises scanning a second ion beam with a second scanning frequency over a surface area of the trench; and
the second scanning frequency is greater than the first scanning frequency.

8. The method according to claim 1, wherein a) comprises:
determining an actual milling depth; and
determining whether the actual milling depth approximately corresponds to the first end-point.

9. The method according to claim 1, further comprising:
acquiring of a surface image of an actual milled surface at an actual depth of the multilayer structure; and
determining the actual depth within the multilayer structure from the surface image.

10. The method according to claim 1, further comprising determining a position of a milling area of the deep trench to be milled with respect to an edit location.

11. The method according to claim 1, further comprising:
drift monitoring a position of the multilayer structure with respect to an ion beam axis; and
during a) or b), drift compensating.

12. The method according to claim 1, further comprising, during a) or b), using a precursor gas to chemically assist an ion beam milling or repair of the multilayer structure.

13. One or more machine-readable hardware storage devices comprising instructions that re executable by one or more processing device to perform operations comprising the method of claim 1.

14. A system, comprising:
one or more processing devices; and
one or more machine-readable hardware storage devices comprising instructions that re executable by one or more processing device to perform operations comprising the method of claim 1.

15. A system, comprising:
a gas field ion source configured to generate an ion beam;
a first nozzle configured to provide a first gas to the gas field ion source;
a second nozzle configured to provide a second gas to the gas field ion source;
a first valve;
a second valve, the first and second gas nozzles being connected via two valves to control provision of the first and second gases to the gas field ion source;
an ion beam column;
a sample enclosure, comprising:
a sample stage configured to hold a sample comprising a multilayer structure; and
a detector configured to attract interaction products generated by an interaction of the ion beam with a sample;
an operation control unit configured to control components of the system, the operation control unit comprising:
an image acquisition control unit connected the detector; and
a source control module connected to the first and second valves to control the first and second valves to control provision of the first and second gases to the gas field ion source,
wherein the source control module is configured to select and adjust an ion beam current of a first ion species generated by the gas field ion source.

16. The system of claim 15, wherein at least one of the following holds:
the source control module is configured to adjust the ion beam of the first ion species generated by the gas field ion source to achieve an areal dosage at a surface of the sample of at most one million ions per square micrometer;
the source control module is configured to adjust the ion beam current of the first ion species generated by the gas field ion source to be less than a picoAmperes;
the source control module is configured to adjust the ion beam of the first ion species to have a kinetic energy less than 10 kilo electron volts; and
the source control module is configured to adjust a ratio of a secondary electron yield to a sputter yield to be greater than one.

17. The system of claim 15, wherein the controller is configured to switch between ion species.

18. The system of claim 15, wherein the controller is configured to switch between a first ion beam with a first ion current and a second ion beam with a second ion current.

19. The system of claim 15, wherein the controller is configured to switch from a first ion beam during a first mode of milling operation to a second ion beam comprising a second ion species during a second mode of milling operation.

20. The system of claim 15, further comprising a third gas nozzle, wherein the third gas nozzle is in the sample enclosure, and the third gas nozzle is configured to provide a precursor gas to the sample enclosure.
